(19) United States
(12) Patent Application Publication
(10) Pub. No.: US 2013/0075824 A1
(43) Pub. Date: Mar. 28, 2013

(54) SEMICONDUCTOR DEVICE AND MANUFACTURING METHOD THEREOF

(71) Applicants: Yoichi FUKUSHIMA, Tokyo (JP); Mika NISHISAKA, Tokyo (JP)

(72) Inventors: Yoichi FUKUSHIMA, Tokyo (JP); Mika NISHISAKA, Tokyo (JP)

(73) Assignee: ELPIDA MEMORY, INC., Tokyo (JP)

(21) Appl. No.: 13/468,595

(22) Filed: May 10, 2012

(30) Foreign Application Priority Data
Sep. 28, 2011 (JP) 2011-213120

(51) Int. Cl. H01L 27/088; H01L 21/02

(52) U.S. Cl. 257/368; 438/381; 257/E27.06; 257/E21.008

(57) ABSTRACT

A semiconductor device has first and second conductive type transistors on a substrate. First conductive type transistor includes: a first lower gate electrode portion on the substrate, including silicon including first impurity ions; a first intervening layer on the first lower gate electrode portion, including silicon including oxygen and/or nitrogen; and a first upper gate electrode portion on the first intervening layer, the first upper gate electrode portion including silicon including the first impurity ions. Second conductive type transistor includes: a second lower gate electrode portion on the substrate, the second lower gate electrode portion including silicon including second impurity ions; a second intervening layer on the second lower gate electrode portion, the second intervening layer including silicon including oxygen and/or nitrogen; and a second upper gate electrode portion on the second intervening layer, the second upper gate electrode portion including silicon including the second impurity ions.

### TECHNICAL FIELD

### Reference to Related Application

This application is based upon and claims the benefit of the priority of Japanese patent application No. 2011-213120, filed on Sep. 28, 2011, the disclosure of which is incorporated herein in its entirety by reference thereto.

The present invention relates to a semiconductor device and a manufacturing method thereof. More specifically, the invention relates to a semiconductor device including a field effect transistor in which a conductive silicon film is applied to a gate electrode thereof, and a manufacturing method of the semiconductor device.

### BACKGROUND

In a semiconductor device including a field effect transistor with a conductive silicon film applied to a gate electrode thereof, resistance of the gate electrode is sometimes reduced in order to reduce a delay of an operation speed of the field effect transistor. Patent Document 1, for example, discloses a method of forming a gate electrode in a field effect transistor of a planar type, using a conductive silicon film. In Patent Document 1, by implanting impurity ions (such as P ions for an nMISFET and B ions for a pMISFET) into non-crystalline silicon films formed over a substrate through a gate insulating film, which will become the gate electrode, resistance of the gate electrode is reduced. This makes it possible to form the field effect transistor of the planar type having the gate electrode thereof with the reduced resistance, to which conductive silicon is applied.

### [Patent Document 1]

JP Patent Kokai Publication No. JP2001-7329A

### SUMMARY

The following analysis is given by the inventors of the present invention.

After studying the technology of implanting the impurity ions to reduce resistances of the silicon films for use as the gate electrode, the inventors have found the following. There is a channel region immediately below the gate electrode of the MISFET, in which carriers drift. Electrical characteristics of the MISFET are affected when the implanted ions have reached this channel region. The threshold voltage of the MISFET is thereby changed.

Assume that the thickness of the gate electrode itself is reduced in a technical trend toward further smaller geometries of the semiconductor device, for example. Then, the implanted impurity ions may readily penetrate into the silicon films (for the gate electrode) and a gate insulating film to reach the channel region.

Further, depending on a requirement for the formation step of the gate electrode and a later manufacturing step, the film thickness of each silicon film (for the gate electrode) may be locally reduced due to polycrystallization of the silicon film (for the gate electrode). In that location where the film thickness of the silicon film is reduced, the implanted impurity ions may readily penetrate through the silicon film (for the gate electrode) and the gate insulating film to reach the channel region.

Further, when heat treatment is performed after the implanted impurity ions have penetrated through the silicon film (for the gate electrode) and the gate insulating film to reach the channel region, the impurity ions in the silicon film (for the gate electrode) may readily penetrate through the gate insulating film to diffuse in the channel region.

Thus, the semiconductor device including the field effect transistor with the conductive silicon film applied to the gate electrode thereof has room for improvement in view of these respects.

According to a first aspect of the present disclosure there is provided a semiconductor device having a first conductive type transistor and a second conductive type transistor formed on a substrate, the first conductive type transistor comprising: a first lower gate electrode portion formed on the substrate, the first lower gate electrode portion comprising silicon including first impurity ions; a first intervening layer formed on the first lower gate electrode portion, the first intervening layer comprising silicon including at least one of oxygen and nitrogen; and a first upper gate electrode portion formed on the first intervening layer, the first upper gate electrode portion comprising silicon including the first impurity ions, and the second conductive type transistor comprising: a second lower gate electrode portion formed on the substrate, the second lower gate electrode portion comprising silicon including second impurity ions; a second intervening layer formed on the second lower gate electrode portion, the second intervening layer comprising silicon including at least one of oxygen and nitrogen; and a second upper gate electrode portion formed on the second intervening layer, the second upper gate electrode portion comprising silicon including the second impurity ions.

According to a second aspect of the present disclosure there is provided a method of manufacturing a semiconductor device comprising: forming a first silicon film on a substrate; forming an intervening layer on the first silicon film, the first intervening layer comprising silicon including at least one of oxygen and nitrogen; forming a second silicon film on the intervening layer; implanting, from the second silicon film side, first impurity ions into a first portion of the first and second silicon films; implanting, from the second silicon film side, second impurity ions into a second portion of the first and second silicon films; thermally annealing, after implanting the first and second impurity ions, the substrate to activate the first and second impurity ions such that the first portion of the first and second silicon films is converted in a first conductive type and the second portion of the first and second silicon films is converted in a second conductive type; selectively removing the first portion of the first and second silicon films to form a first gate electrode having the first conductive type; and selectively removing the second portion of the first and second silicon films to form a second gate electrode having the second conductive type.

The meritorious effects of the present invention are summarized as follows, without limitation, thereto. According to the present disclosure, when the impurity ions are implanted in order to cause each of the silicon films to be conductive, the impurity ions are hard to reach a channel region below the silicon films due to the intervening layer disposed between the gate electrode films (between the silicon films). As a result, a variation in the threshold of the transistor can be reduced.

### BRIEF DESCRIPTION OF THE DRAWINGS

FIG. 1 is a sectional view schematically showing a configuration of a semiconductor device according to a first exemplary embodiment of the present disclosure;

FIGS. 2A to 2D are sectional views schematically showing steps of a manufacturing method of the semiconductor device in the first exemplary embodiment;

FIGS. 3A to 3C are sectional views schematically showing steps of the manufacturing method of the semiconductor device in the first exemplary embodiment following the steps in FIGS. 2A to 2D;

FIGS. 4A and 4B are respectively a plan view and a sectional view taken along a line X-X′ in FIG. 4A, each schematically showing a configuration of a semiconductor device in a second exemplary embodiment of the present disclosure;

FIGS. 5A to 5C are sectional views schematically showing steps of a manufacturing method of the semiconductor device in the second exemplary embodiment;

FIGS. 6A to 6C are sectional views schematically showing steps of the manufacturing method of the semiconductor device in the second exemplary embodiment following the steps in FIGS. 5A to 5C;

FIGS. 7A to 7C are sectional views schematically showing steps of the manufacturing method of the semiconductor device in the second exemplary embodiment following the steps in FIGS. 6A to 6C;

FIG. 8 is a plan view schematically showing a configuration of a semiconductor device in a third exemplary embodiment of the present disclosure;

FIGS. 9A and 9B are respectively a plan view and a sectional view taken along a line X-X′ in FIG. 9A, each schematically showing a configuration of a peripheral circuit region of the semiconductor device in the third exemplary embodiment;

FIGS. 10A and 10B are respectively a plan view and a sectional view taken along a line Y-Y′ in FIG. 10A, each schematically showing a configuration of a memory cell region of the semiconductor device in the third exemplary embodiment;

FIGS. 11A and 11B are sectional views schematically showing steps of a manufacturing method of the semiconductor device in the third exemplary embodiment;

FIGS. 12A and 12B are sectional views schematically showing steps of the manufacturing method of the semiconductor device in the third exemplary embodiment, following the steps in FIGS. 11A and 11B;

FIGS. 13A and 13B are sectional views schematically showing steps of the manufacturing method of the semiconductor device in the third exemplary embodiment, following the steps in FIGS. 12A and 12B;

FIGS. 14A and 14B are sectional views schematically showing steps of the manufacturing method of the semiconductor device in the third exemplary embodiment, following the steps in FIGS. 13A and 13B;

FIGS. 15A and 15B are sectional views schematically showing steps of the manufacturing method of the semiconductor device in the third exemplary embodiment, following the steps in FIGS. 14A and 14B;

FIGS. 16A and 16B are a plan view and a sectional view taken along a line X-X′ in FIG. 16A, each schematically showing a configuration of a peripheral circuit region of a semiconductor device in a fourth exemplary embodiment of the present disclosure; and

FIGS. 17A and 17B are sectional views schematically showing steps of a manufacturing method of the semiconductor device in the fourth exemplary embodiment.

### PREFERRED MODES

### First Exemplary Embodiment

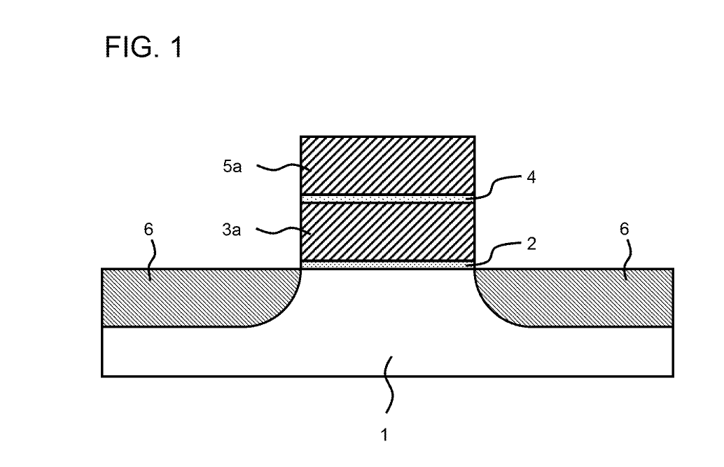

A semiconductor device according to a first exemplary embodiment of the present disclosure will be described using drawings. FIG. 1 is a sectional view schematically showing a configuration of a semiconductor device according to the first exemplary embodiment.

Referring to FIG. 1, the semiconductor device includes a field effect transistor of a planar type, having a gate electrode formed of polycrystalline silicon.

In the field effect transistor, a first gate electrode film 3a is formed over a main surface of a semiconductor substrate 1 (such as a silicon substrate) through a gate insulating film 2 (formed of a silicon oxide film, for example). The first gate electrode film 3a is a conductive film mainly made of silicon including an impurity (such as P (phosphor) ions or B (boron) ions) that is to be of a first conductivity type. An intervening layer 4 is formed on the first gate electrode film 3a. The intervening layer 4 is a layer (such as an insulating layer) between the first gate electrode film 3a and a second gate electrode film 5a, and is mainly made of silicon including at least one of oxygen and nitrogen. The second gate electrode film 5a is formed on the intervening layer 4. The second gate electrode film 5a is a conductive film made of silicon including the impurity (that is the same as the impurity of the first gate electrode film 3a) that is to be of the first conductivity type. The first gate electrode film 3a, the intervening layer 4, and the second gate electrode film 5a form the gate electrode of the first conductivity type.

A source/drain region 6 is formed on each side of a channel region (portion of the semiconductor substrate 1) under the gate insulating film 2 of the field effect transistor. The source/drain region 6 is a region mainly made of silicon including an impurity (such as P ions or B ions) that is to be of the first conductivity type.

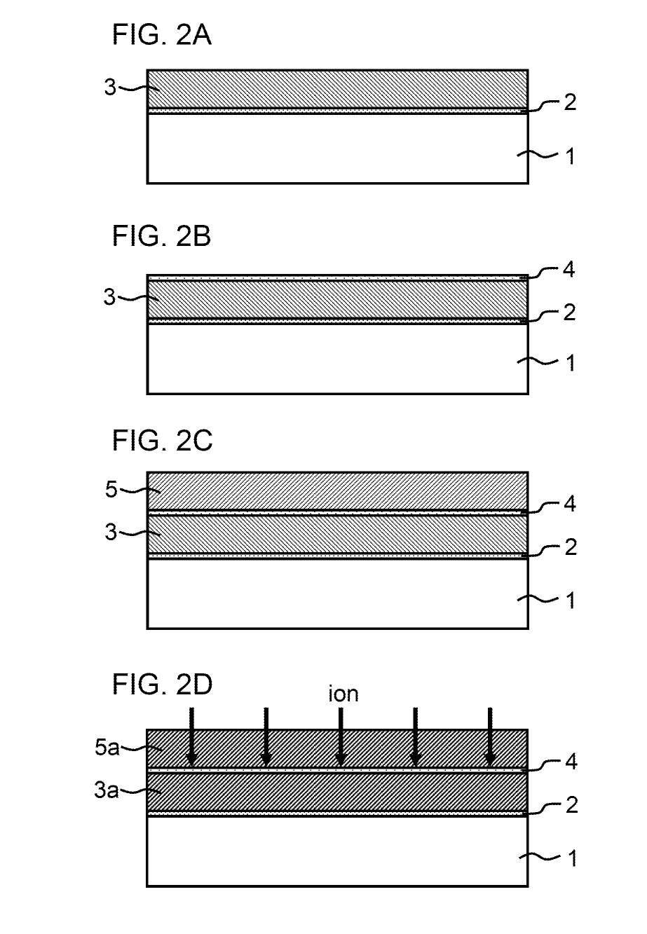

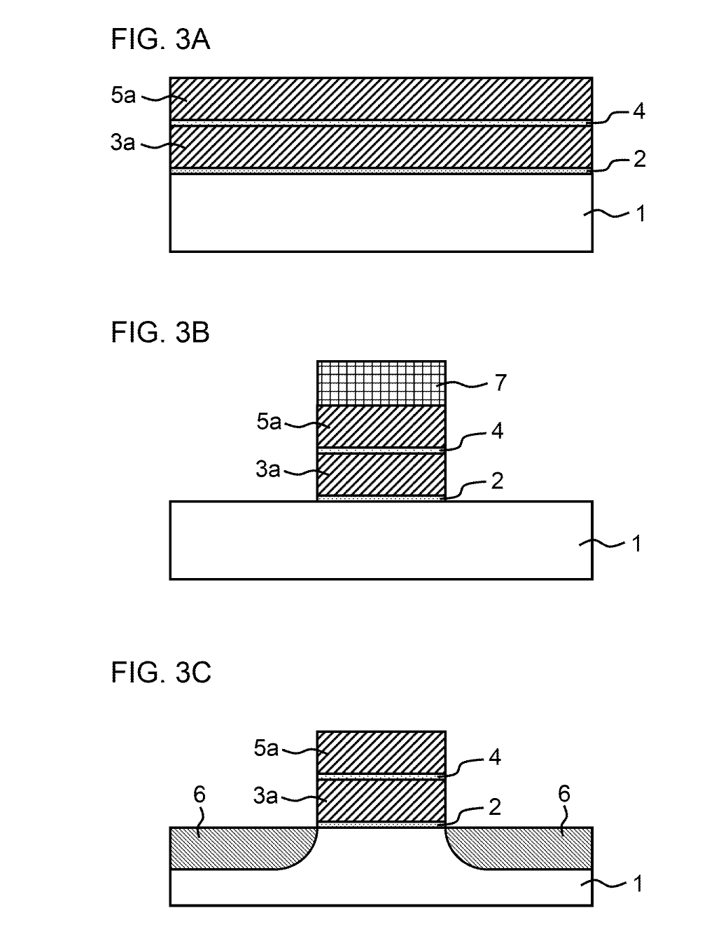

Next, a manufacturing method of the semiconductor device according to the first exemplary embodiment will be described using drawings. FIG. 2A to FIG. 3C are sectional views schematically showing steps of the manufacturing method of the semiconductor device according to the first exemplary embodiment.

First, the gate insulating film 2 is formed on the main surface of the semiconductor substrate 1. Then, a first silicon film 3 mainly made of silicon is formed on the gate insulating film 2 (in step A1; refer to FIG. 2A).

The gate insulating film 2 can herein be formed by thermal oxidation, or plasma oxynitriding, for example. The first silicon film 3 can be formed by a CVD (Chemical Vapor Deposition; chemical vapor deposition) method, for example. The first silicon film 3 is polycrystallized by a later heat treatment or the like. The first silicon film 3 formed in step A1 may be polycrystalline or amorphous. However, in order to reduce an increase in surface roughness of the first silicon film 3 resulting from enlargement of the grain size when the polycristallization is performed by heating, it is preferable that the first silicon film 3 be formed in an amorphous state, in step A1. Preferably, the first silicon film 3 has a thickness of not more than 30 nm.

Next, at least one of oxygen and nitrogen is supplied to the surface of the first silicon film 3, thereby forming the intervening layer 4 mainly made of silicon including the at least one of oxygen and nitrogen (in step A2; refer to FIG. 2B).

The intervening layer 4 herein has a thickness of not less than one molecule layer and not more than 3.0 nm. More preferably, the intervening layer 4 has a thickness of not more than 2.0 nm. The thickness of the intervening layer 4 of not less than one molecule layer is set because, when a location without having the intervening layer 4 is present (a gap is present) on a two-dimensional plane, this gap will cause penetration of B when the B is implanted. Alternatively, the gap will serve as the core of a grain to cause partial enlargement (growth) of the grain when heat treatment is performed after a second silicon film 5 has been formed. Accordingly, it is necessary to form the intervening layer on the two-dimensional plane with no gap. The thickness of the intervening layer 4 of not more than 2.0 nm or 3.0 nm is set because, since the first silicon film 3 and the second silicon film 5 need to maintain good electrical conductivity, the thickness of the intervening layer 4 of more than 2.0 nm or 3.0 nm is not desirable in terms of electrical characteristics.

Preferably, the intervening layer 4 is formed at a position lower than a half of the entire film thickness of the gate electrode (film thickness from the lower surface of the first silicon film 3 to the upper surface of a second silicon film 5 on the page of FIG. 2C). More specifically, it is more preferable that the intervening layer 4 be formed at a position of 30 nm or less of distance from an interface between the gate insulating film 2 and the first silicon film 3 (in other words, the thickness of the first silicon film 3 to be formed in step A1 is set to 30 nm or less). That is, it is preferable that the thickness of the first silicon film 3 be 30 nm or less in order to prevent enlargement (excess growth) of the crystal grain when the first silicon film 3 is polycrystallized by the later heat treatment.

As a method of forming the intervening layer 4, the following two methods can be pointed out. In a first method of forming the intervening layer 4, after the first silicon film 3 has been formed in a chamber, at least one of an oxygen gas and a nitrogen gas is supplied to the same chamber. With this arrangement, a thin silicon oxide film, a thin silicon nitride film, or a thin silicon oxynitride film is formed on the surface of the first silicon film 3. Then, the second silicon film (indicated by reference numeral 5 in FIG. 2C) is formed in the same chamber. In a second method of forming the intervening layer 4, after the first silicon film 3 has been formed in a chamber, the resultant product is transferred to a different chamber to be subjected to an oxidation process, a nitriding process, or an oxynitriding process. Alternatively, after the resultant product has been formed in the chamber, the first silicon film 3 is transferred to the different chamber. Then, the silicon oxide film, the silicon nitride film, or the silicon oxynitride film, which will become the intervening layer 4, is formed on the first silicon film 3. Then, the second silicon film (indicated by reference numeral 5 in FIG. 2C) is formed in the chamber where the first silicon film 3 has been formed.

Next, the second silicon film 5 mainly made of silicon is formed on the intervening layer 4 (in step A3; refer to FIG. 2C).

Herein, the second silicon film 5 can be formed by the CVD method, for example. Though the second silicon film 5 is polycrystallized by a later heat treatment or the like, the second silicon film 5 formed in step A3 may be polycrystalline or amorphous.

Next, impurity ions (such as P ions or B ions) are implanted (introduced) into the first silicon film (indicated by reference numeral 3 in FIG. 2C) and the second silicon film (indicated by reference numeral 5 in FIG. 2C) from above the second silicon film 5 (in step A4; refer to FIG. 2D). This causes the first silicon film (indicated by reference numeral 3 in FIG. 2C) and the second silicon film (indicated by reference numeral 5 in FIG. 2C) to become the first gate electrode film 3a and the second gate electrode film 5a including the impurity ions.

Next, the substrate is activation annealed (in step A5; refer to FIG. 3A). That is, by heating the substrate, the introduced impurity ions are diffused in the entire first gate electrode film 3a and the entire second gate electrode film 5a, and are activated.

While the impurity ions diffuse in the first gate electrode film 3a by the heat treatment, the intervening layer 4 becomes a stopper, so that an amount of the impurity ions that will reach the channel region decreases, in step A5. With this arrangement, a variation in the threshold voltage of the transistor can be further reduced. This activation annealing in step A5 can be applied when the ions are implanted in step A4, but is not limited to this timing. This activation annealing may be used in combination with a different heat treatment such as annealing to be performed later than this activation annealing step, after source/drain regions have been formed. The present disclosure can be applied to any one of these steps to achieve the similar effect.

Next, a resist 7 is formed on a region that will be left as the gate electrode. Then, the second gate electrode film 5a, the intervening layer 4, the first gate electrode film 3a, and the gate insulating film 2 are etched using the resist 7 as a mask until the semiconductor substrate 1 is exposed (in step A6; refer to FIG. 3B).

Finally, by implanting impurity ions into the semiconductor substrate 1 using the resist 7 as the mask, source/drain regions 6 are formed. Then, the resist 7 is removed (in step A7; refer to FIG. 3C). With this arrangement, the semiconductor device that is the same as in FIG. 1 is manufactured.

According to the first exemplary embodiment, by interposing the intervening layer 4 mainly made of silicon and including at least one of oxygen and nitrogen between the silicon films 3 and 5, it becomes difficult for the impurity ions to reach the channel region under the silicon film 3 when the impurity ions are implanted so as to cause the silicon films 3 and 5 to be conductive (reduce a resistance of the gate electrode). As a result, a variation in the threshold voltage of the transistor can be reduced.

### Second Exemplary Embodiment

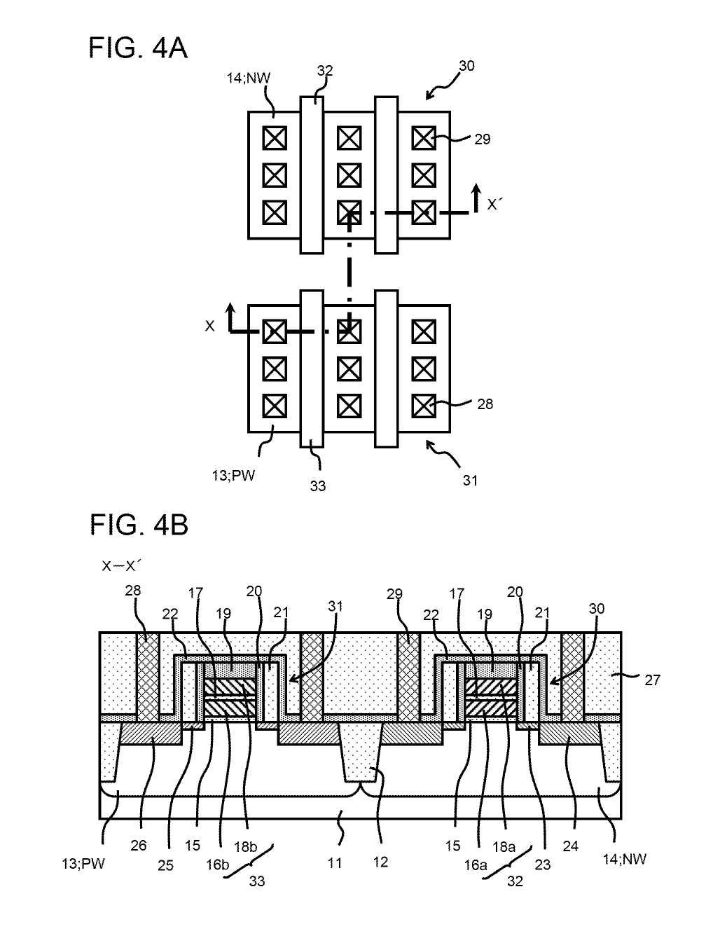

A semiconductor device according to a second exemplary embodiment of the present disclosure will be described using drawings. FIGS. 4A and 4B are respectively a plan view and a sectional view taken along a line X-X′ in FIG. 4A. Each of FIGS. 4A and 4B schematically shows a configuration of the semiconductor device according to the second exemplary embodiment.

In the second exemplary embodiment, the gate electrode according to the first exemplary embodiment is applied to a gate electrode of a CMOS (Complementary Metal Oxide Semiconductor; complementary metal oxide film semiconductor) transistor in which MOSFETs (Metal-Oxide-Semiconductor Field-Effect Transistors; metal-oxide-semiconductor field-effect transistors) are disposed in a complementary fashion.

Referring to FIGS. 4A and 4B, STIs (Shallow Trench Isolations; formed of a silicon oxide film, for example) 12 for electrically isolating elements (transistors) are formed in a semiconductor substrate (such as a silicon substrate) 11. In the semiconductor device, an N-well 14 is formed in a region of the semiconductor substrate 11 surrounded by the STIs 12 in which a P-channel transistor 30 is formed. A P-well 13 is formed in a region of the semiconductor substrate 11 surrounded by the STIs 12 in which an N-channel transistor 31 is formed. The P-well 13 is a well mainly made of silicon and including a P-type impurity. The N-well 14 is a well mainly made of silicon and including an N-type impurity.

In the region where the P-channel transistor 30 is formed, a P-type first silicon film 16a is formed over a main surface of the N-well 14 through a gate insulating film 15 (made of a silicon oxide film, for example). The p-type first silicon film 16a is a conductive film mainly made of silicon and including a P-type impurity. An intervening layer 17 is formed on the P-type first silicon film 16a. The intervening layer 17 is a layer (such as an insulating film) interposed between the P-type first silicon film 16a and a P-type second silicon film 18a, and is mainly made of silicon and includes at least one of oxygen and nitrogen. The P-type second silicon film 18a is formed on the intervening layer 17. The P-type second silicon film 18a is a conductive film mainly made of silicon and includes the P-type impurity (that is the same as the impurity of the P-type first silicon film 16a). The P-type first silicon film 16a, the intervening layer 17, and the P-type second silicon film 18a form a P-type gate electrode 32. A protective film 19 (made of a silicon nitride film, for example) is formed on the P-type second silicon film 18a. Sidewalls of the protective film 19, the P-type second silicon film 18a, the intervening layer 17, the P-type first silicon film 16a, and the gate insulating film 15 are covered with sidewalls 21 (made of a silicon oxide film, for example) with interposition of offset spacers 20 (made of a silicon nitride film, for example). A P− type LDD (Lightly Doped Drain) region 23 is formed under each sidewall 21 in the N-well 14. A P+ type source/drain region 24 is formed in a region of the N well 14 between the P− type LDD region 23 and the STI 12. The P− type LDD region 23 is a region mainly made of silicon and includes a P-type impurity. The P− type LDD region 23 has a lower impurity concentration than the P+ type source/drain region 24. The P+ type LDD region 24 is a region mainly made of silicon and includes the P-type impurity. The P+ type LDD region 24 has a higher impurity concentration than the P− type source/drain region 23.

In a region where the N-channel transistor 31 is formed, an N-type first silicon film 16b is formed over a main surface of the P well 13 with interposition of the gate insulating film 15 (made of the silicon oxide film, for example). The N-type first silicon film 16b is a conductive film mainly made of silicon and includes an N-type impurity. An intervening layer 17 is formed on the N-type first silicon film 16b. Like the intervening layer 17 in the P-channel transistor 30, the intervening layer 17 formed on the N-type first silicon film 16b is a layer (such as an insulating film) interposed between the N-type first silicon film 16b and an N-type second silicon film 18b, and is mainly made of silicon and includes at least one of oxygen and nitrogen. The N-type second silicon film 18b is formed on the intervening layer 17. The N-type second silicon film 18b is a conductive film mainly made of silicon and includes the N-type impurity (that is the same as the impurity of the N-type first silicon film 16b). The N-type first silicon film 16b, the intervening layer 17, and the N-type second silicon film 18b form an N-type gate electrode 33. The protective film 19 (made of the silicon nitride film, for example) is formed on the N-type second silicon film 18b. Sidewalls of the protective film 19, the N-type second silicon film 18b, the intervening layer 17, the N-type first silicon film 16b, and the gate insulating film 15 are covered with the sidewalls 21 (made of the silicon oxide film, for example) via (i.e. with interposition of) the offset spacers 20 (formed of the silicon nitride film, for example). An N− type LDD region 25 is formed under each sidewall 21 in the P-well 13. An N+ type source/drain region 26 is formed in a region of the P well 13 between the N− type LDD region 25 and the STI 12. The N− type LDD region 25 is a region mainly made of silicon and includes an N-type impurity. The N− type LDD region 25 has a lower impurity concentration than the N+ type source/drain region 26. The N+ type source/drain region 26 is a region mainly made of silicon and includes the N-type impurity. The N+ type source/drain region 26 has a higher impurity concentration than the N− type LDD region 25.

An interlayer insulating film 27 (made of a silicon oxide film, for example) is formed over the substrate including the P-channel transistor 30, the N-channel transistor 31, and the STIs 12 via a liner film 22 (made of a silicon nitride film, for example). In the region where the P-channel transistor 30 is formed, contact plugs 29 (made of tungsten, for example) connected to the P+ type source/drain regions 24 are formed, penetrating through the interlayer insulating film 27 and the liner film 22. In the region where the N-channel transistor 31 is formed, contact plugs 28 (made of tungsten, for example) connected to the N+ type source/drain regions 26 are formed, penetrating through the interlayer insulating film 27 and the liner film 22.

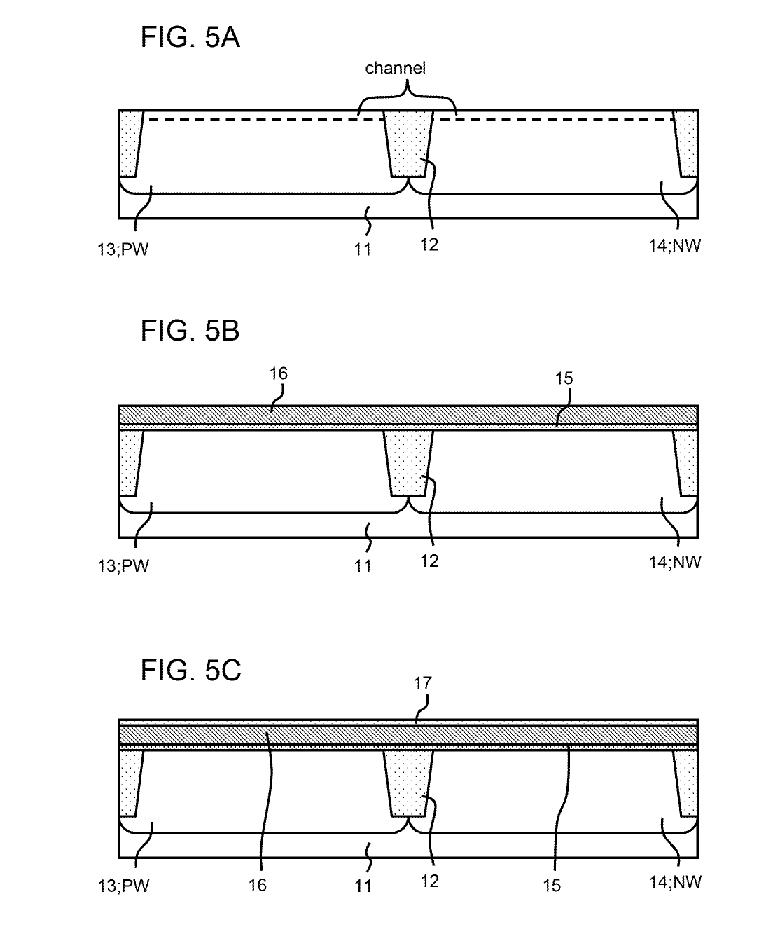

Next, a method of manufacturing the semiconductor device according to the second exemplary embodiment will be described using drawings. FIGS. 5A to 7C are sectional views schematically showing steps of the method of manufacturing the semiconductor device according to the second exemplary embodiment.

First, the STIs 12 are formed in device isolation regions on the semiconductor substrate 1. Then, the P-well 13 and the N-well 14 are formed in the semiconductor substrate 11, and then a channel is formed (in step B1; refer to FIG. 5A).

The STIs 12, the P-well 13 (formed by ion implantation or the like), the N-well 14 (formed by ion implantation or the like), and the channel (formed by ion implantation or the like) can be formed by a known method. The channel will not hereinafter be illustrated.

Next, the gate insulating film 15 is formed on the main surface of the substrate including the STIs 12, the P-well 13, and the N-well 14. Then, a first silicon film 16 mainly made of silicon is formed on the gate insulating film 15 (in step B2; refer to FIG. 5B).

The gate insulating film 15 can herein be formed by thermal oxidation or plasma oxynitriding, for example. The first silicon film 16 can be formed by a CVD method, for example. Though the first silicon film 16 is polycrystallized by a later heat treatment or the like, the first silicon film 16 formed in this step may be polycrystalline or amorphous. However, in order to reduce an increase in surface roughness of the first silicon film 16 resulting from enlargement of the grain size (grain growth) when the polycrystallization is performed by heating, it is preferable that the first silicon film 16 be formed in an amorphous state, in step B2. Preferably, the first silicon film 16 has a thickness of not more than 30 nm.

Next, at least one of oxygen and nitrogen is supplied to the surface of the first silicon film 16, thereby forming the intervening layer 17 mainly made of silicon and including the at least one of oxygen and nitrogen (in step B3; refer to FIG. 5C).

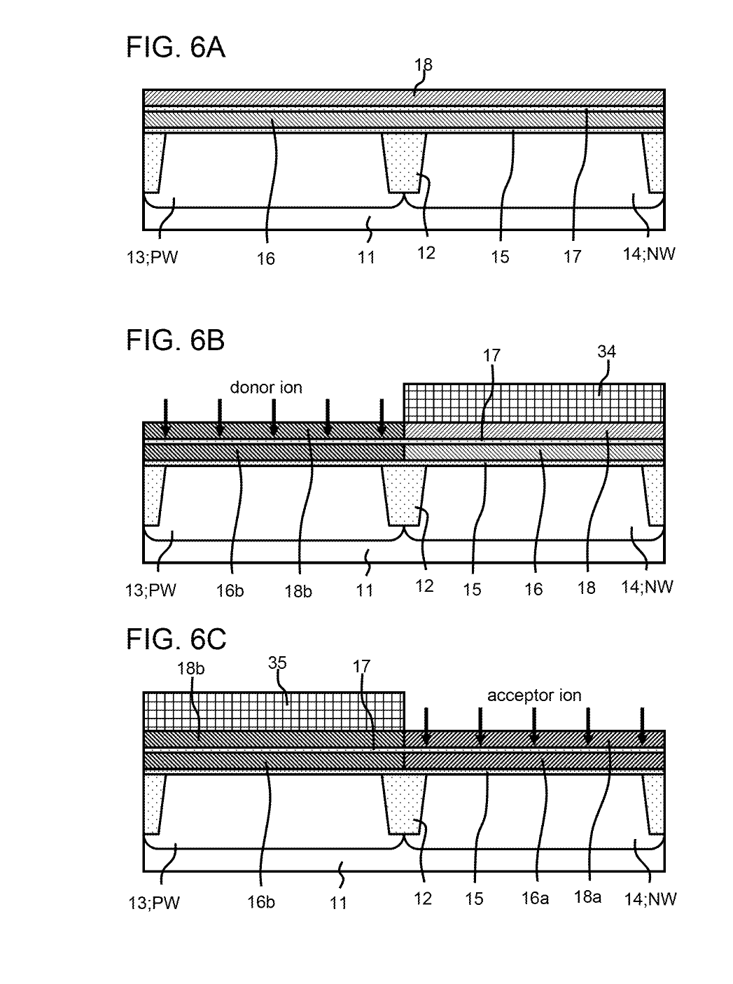

The intervening layer 17 herein has a thickness of at least one molecule layer and not more than 3.0 nm. More preferably, the intervening layer 17 has a thickness of not more than 2.0 nm. Preferably, the intervening layer 17 is formed at a position lower than a half of the entire film thickness of each gate electrode (film thickness from the lower surface of the first silicon film 16 to the upper surface of a second silicon film 18 on the page of FIG. 6A). More specifically, it is more preferable that the intervening layer 17 be formed at a position of not more than 30 nm from the interface between the gate insulating film 15 and the first silicon film 16 (in other words, the thickness of the first silicon film 3 to be formed in step B2 is set to 30 nm or less).

As a method of forming the intervening layer 17, the following two methods can be pointed out. In a first method of forming the intervening layer 17, after the first silicon film 16 has been formed in a chamber, at least one of an oxygen gas and a nitrogen gas is supplied to the same chamber. With this arrangement, a thin silicon oxide film, a thin silicon nitride film, or a thin silicon oxynitride film that will become the intervening layer 17 is formed on the surface of the first silicon film 16. Then, the second silicon film (indicated by reference numeral 18 in FIG. 6A) is formed in the same chamber. In a second method of forming the intervening layer 17, after the first silicon film 16 has been formed in a chamber, the substrate is transferred to a different chamber to be subjected to an oxidation process, a nitriding process, or an oxynitriding process. Alternatively, after the first silicon film 16 has been formed in the chamber, the substrate is transferred to the different chamber. Then, the silicon oxide film, the silicon nitride film, or the silicon oxynitride film, which will become the intervening layer 17, is formed on the first silicon film 16. Then, the second silicon film (indicated by reference numeral 18 in FIG. 6A) is formed in the chamber where the first silicon film 16 has been formed.

Next, the second silicon film 18 mainly made of silicon is formed on the intervening layer 17 (in step B4; refer to FIG. 6A).

The second silicon film 18 can herein be formed by the CVD method, for example. Though the second silicon film 18 is polycrystallized by a later heat treatment or the like, the second silicon film 18 formed in step B4 may be polycrystalline or amorphous. However, in order to reduce an increase in surface roughness of the second silicon film 18 resulting from enlargement of the grain size when the polycrystallization is performed by heating, it is preferable that the second silicon film 18 be formed in an amorphous state in step B4.

Next, a photoresist 34 is formed on the second silicon film 18 in a region where the N-well 14 is formed. Then, donor ions (of As, P, or the like) are implanted into the silicon films 18b and 16b in a region where the P-well 13 is formed (in step B5; refer to FIG. 6B). Thereafter, the photoresist 34 is removed.

Next, a photoresist 35 is formed on the N-type second silicon film 18b in the region where the P-well 13 is formed. Then, acceptor ions (of B or the like) are implanted into the silicon films 18a and 16a in the region where the N-well 14 is formed (in step B6; refer to FIG. 6C). Thereafter, the photoresist 35 is removed.

The step B5 may be interchanged with the step B6. When the step B5 and the step B6 are executed, the intervening layer 17 acts as a stopper to prevent the implanted ions from reaching a channel region. This can reduce a variation in the threshold voltage of each transistor.

Since B (boron) has a comparatively small atomic weight, the boron ions readily reach the channel region when implanted. In view of this respect, the configuration of the present disclosure is more effective when applied to the P-channel transistor (indicated by reference numeral 30 in FIGS. 4A and 4B) including the P-type gate electrode (indicated by reference numeral 32 in FIGS. 4A and 4B) in which the acceptor ions (of B in particular) have been implanted into the silicon films 18a and 16a.

A process in which the substrate needs to be heated (such as a thermal oxidation process for forming a gate insulating film for the transistors to be formed in a different process, for example) may be included before the ion implantation processes (in steps B5 to B6) after the silicon film formation processes (in steps B2 to B4). In this case, each silicon film is polycrystallized, and due to grain enlargement, roughness may increase. When the roughness increases, the thickness of the silicon film may be locally reduced. Then, the implanted impurity ions may readily penetrate into the channel region. According to the second exemplary embodiment, the intervening layer 17 is disposed between the silicon films 16 and 18. Thus, the grain enlargement can be reduced, thereby allowing reduction in the number of locations where the thickness of each of the silicon films 16 and 18 is locally reduced. Accordingly, the implanted ions may be prevented from reaching the channel region.

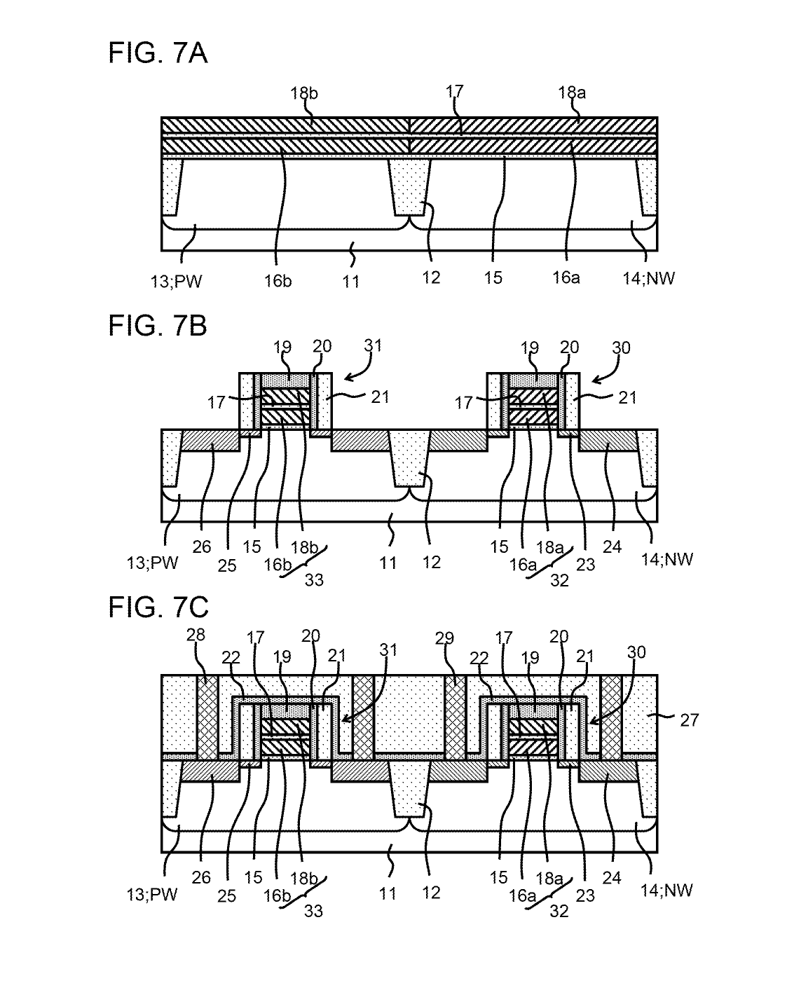

Next, the entire substrate is heated (for activation annealing) (in step B7; refer to FIG. 7A).

Impurity ions implanted into the silicon films 16a, 16b, 18a and 18b are diffused in the entire silicon films 16a, 16b, 18a and 18b by the heating treatment, for activation in step B7. Particularly, while the impurity ions diffuse in the first silicon films 16a and 16b due to the heat treatment, the intervening layer 17 becomes the stopper to reduce the amount of the impurity ions that will reach the channel region. This can further reduce a variation in the threshold voltage of each transistor. Annealing for impurity activation may be applied when each of the ion implantation processes (in steps B5 and B6) is executed, and is not limited to this timing.

Step B7 may be used in combination with a different heat treatment such as annealing in a subsequent LDD formation process (in step B8) and a source/drain formation process (in step B8). In either case, the present disclosure is likewise effective.

Next, the protective film 19 (made of the silicon nitride film, for example) is formed on the second silicon films 18a and 18b in regions that will be left as the gate electrodes 32 and 33. Then, using the protective film 19 as a mask, the second silicon films 18a and 18b, the intervening layer 17, the first silicon films 16a and 16b, and the gate insulating film 15 are etched until the P-well 13 and the N-well 14 are exposed. Then, sidewall-like offset spacers 20 (made of the silicon nitride film, for example) are formed on the sidewalls of the protective film 19, the P-type second silicon film 18a, the intervening layer 17, the P-type first silicon film 16a, and the gate insulating film 15 on the formation region of the N-well 14 and the sidewalls of the protective film 19, the N-type second silicon film 18b, the intervening layer 17, the N-type first silicon film 16b, and the gate insulating film 15 of the formation region of the P-well 13. Then, the LDD regions (which are the N− type LDD regions 25 in the P-well 13 and the P− type LDD regions 23 in the N-well 14) are formed. Then, the sidewalls 21 (made of the silicon oxide film, for example) are formed on sidewalls of the offset spacers 20. Thereafter, the source/drain regions (which are the N+ type source/drain regions 26 in the P-well 13 and the P+ type source/drain regions 24 in the N-well 14) are formed (in step B8; refer to FIG. 7B). With this arrangement, the transistors 30 and 31 are formed.

The protective film 19 can herein be formed by forming the silicon nitride film on the second silicon films 18a and 18b by the CVD method or the like, forming a photoresist on the silicon nitride film in regions that will be left as the gate electrodes 32 and 33, and then etching the silicon nitride film using the photoresist as a mask until the second silicon films 18a and 18b are exposed.

The offset spacers 20 are formed by forming the silicon nitride film over the entire surface of the substrate including the gate electrodes 32 and 33 by the CVD method or the like, and then by etching back the silicon nitride film until the P-well 13 and the N-well 14 are exposed.

With respect to formation of the LDD regions, when the N− type LDD regions 25 are formed in the P-well 13, a photoresist is formed on a region where the N-well 14 including the P-type gate electrode 32 is formed, donor ions (of As, P, or the like) are implanted into the P-well 13, using the photoresist as a mask. Then, the photoresist is removed. When the P− type LDD regions 23 are formed in the N-well 14, a photoresist is formed on a region where the P-well 13 including the N-type gate electrode 33 is formed, and acceptor ions (of B or the like) are implanted into the N-well 14, using the photoresist as a mask. Then, the photoresist is removed.

The sidewalls 21 can be formed by forming the silicon oxide film over the entire surface of the substrate including the offset spacers 20 and the gate electrodes 32 and 33 by the CVD method or the like, and then etching back the silicon oxide film until the N− type LDD region 25 and the P− type LDD region 23 are exposed.

Further, with respect to formation of the source/drain regions, when the N+ type source/drain regions 26 are formed in the P-well 13, a photoresist is formed on the region in which the N-well 14 including the P-type gate electrode 32 is formed, donor ions (of As, P, or the like) are implanted into the P-well 13, using the photoresist as a mask. Then, the photoresist is removed. When the P+ type source/drain regions 24 are formed in the N-well 14, a photoresist is formed on the region where the P-well 13 including the N-type gate electrode 33 is formed, and acceptor ions (of B or the like) are implanted into the N-well 14, using the photoresist as a mask. Then, the photoresist is removed.

Finally, the liner film 22 (made of the silicon nitride film, for example) is formed over the entire surface of the substrate including the P-channel transistor 30 and the N-channel transistor 31. Then, the interlayer insulating film 27 is formed over the liner film 22. Then, hole(s) leading to the source/drain regions 24 and 26 are formed in the interlayer insulating film 27 and the liner film 22. Then, the contact plugs 28 and 29 are formed in the hole(s) (in step B9; refer to FIG. 7C). After step B9, known steps of forming interconnects, an interlayer insulating film, via plugs, and upper layer interconnects follow.

The liner film 22 can herein be formed by forming the silicon nitride film by the CVD method, for example. An SOD (Spin on Dielectric; spin on interlayer insulating film) can be used as the interlayer insulating film 27. The hole(s) can be formed by forming on the interlayer insulating film 27 a photoresist opening in locations where the hole(s) are formed, etching the interlayer insulating film 27 and the liner film 22 until the source/drain regions 24 and 26 are exposed, using the photoresist as a mask, and then removing the photoresist. The contact plugs 28 and 29 can be formed by forming a conductive film (made of tungsten, for example) on the interlayer insulating film 27 including the hole(s), and polishing the conductive film by CMP (Chemical Mechanical Polishing; chemical mechanical polishing) until the interlayer insulating film 27 is exposed.

According to the second exemplary embodiment, the intervening layer 17 becomes the stopper when the ion implantation processes (in steps B5 and B6; refer to FIGS. 6B and 6C) are performed. The implanted ions may be prevented from reaching the channel region. This can reduce a variation in the threshold voltage of each of the transistors 30 and 31.

A process in which the substrate needs to be heated (such as a thermal oxidation process for forming a gate insulating film for the transistors to be formed in a different process, for example) may be included before the ion implantation processes (in steps B5 and B6: refer to FIGS. 6B and 6C) after the silicon film formation processes (in steps B2 to B4; refer to FIGS. 5B to 6A). In such a case, each silicon film is polycrystallized, and due to grain enlargement, roughness may increase. When the roughness increases, the thickness of the silicon film may be locally reduced. Then, the implanted impurity ions may readily penetrate into the channel region. According to the second exemplary embodiment, the intervening layer 17 is disposed between the silicon films 16 and 18. Thus, the grain enlargement (excessive grain growth) can be reduced, thereby allowing reduction in the number of locations where the thickness of each of the silicon films 16 and 18 is locally reduced. Accordingly, the implanted ions may be prevented from reaching the channel region.

Further, according to the second exemplary embodiment, while the impurity ions diffuse in the first silicon film 16 due to the heat treatment (in step B7; refer to FIG. 7A), the intervening layer 17 becomes the stopper. An amount of the impurity ions that will reach the channel region is thereby reduced. This can further reduce a variation of the threshold voltage of each of the transistors 30 and 31.

### Third Exemplary Embodiment

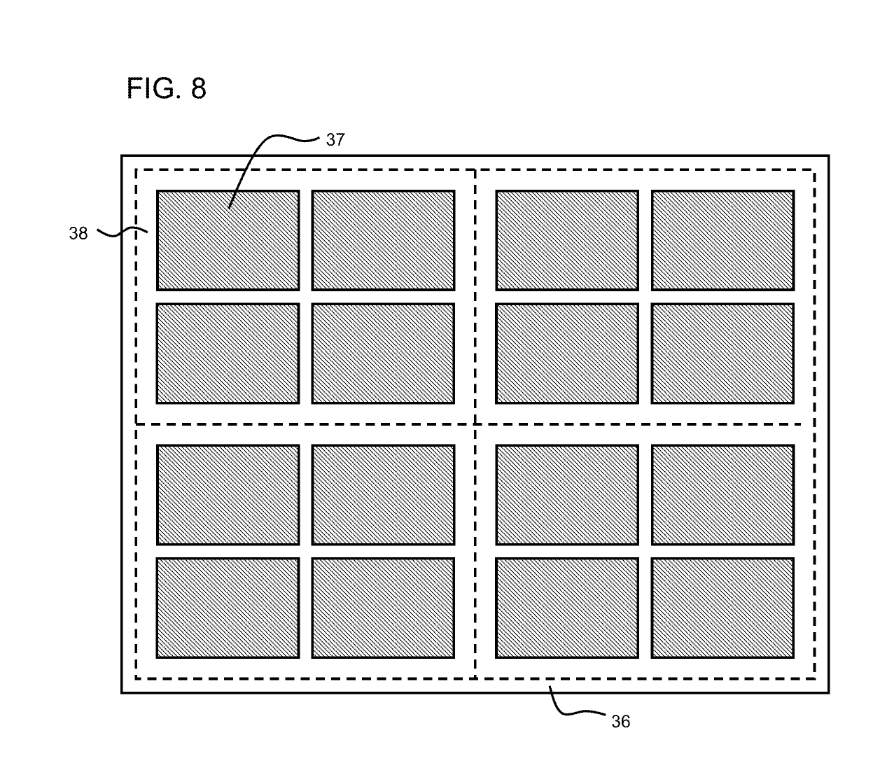

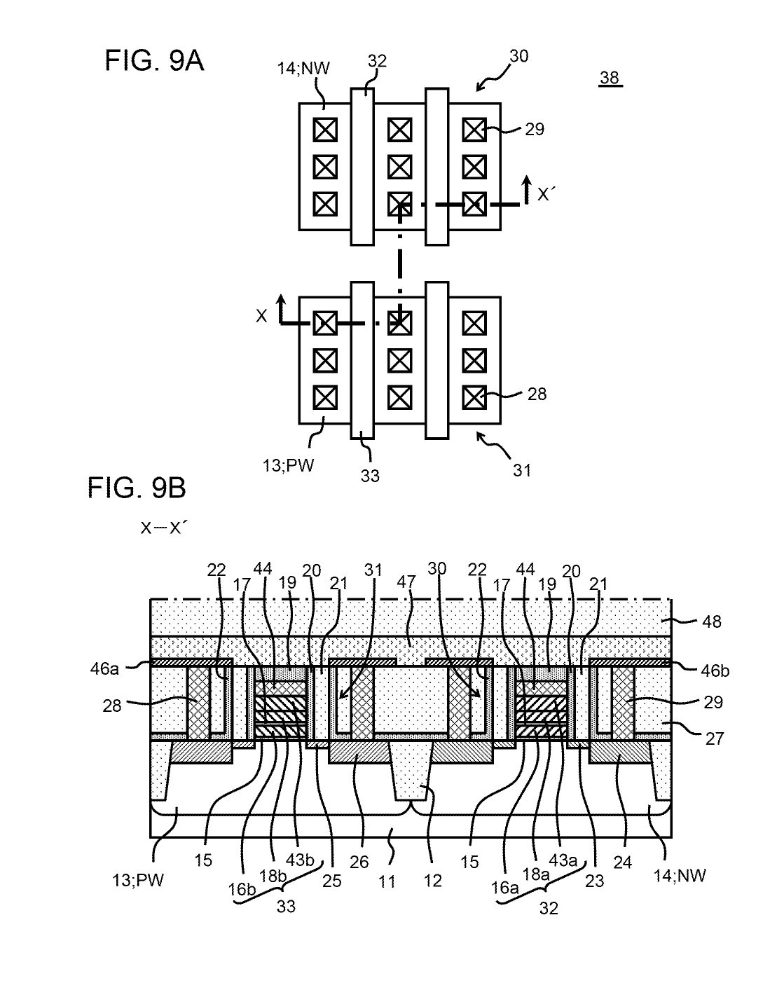

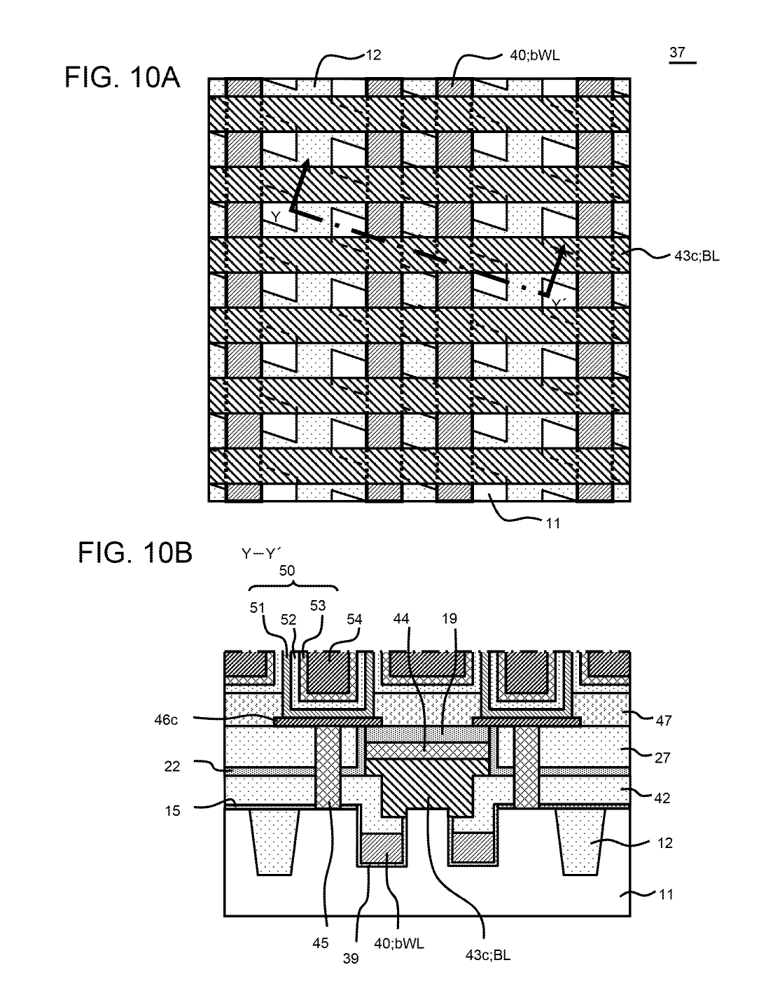

A semiconductor device according to a third exemplary embodiment of the present disclosure will be described using drawings. FIG. 8 is a plan view schematically showing a configuration of the semiconductor device according to the third exemplary embodiment. FIGS. 9A and 9B are respectively a plan view and a sectional view taken along a line X-X′ of FIG. 9A, each schematically showing a configuration of a peripheral circuit region of the semiconductor device according to the third exemplary embodiment. FIGS. 10A and 10B are respectively a plan view and a sectional view taken along a line Y-Y′ of FIG. 10A, each schematically showing a configuration of a memory cell region of the semiconductor device according to the third exemplary embodiment.

In the third exemplary embodiment, the structures of the gate electrodes (indicated by reference numerals 32 and 33 in FIGS. 4A and 4B) in the second exemplary embodiment are respectively applied to gate electrodes 32 and 33 in a peripheral circuit region 38 of a 6F2/bWL-type DRAM (Dynamic Random Access Memory) chip 36.

Referring to FIG. 8, in the DRAM chip 36, a plurality of memory cell regions 37 with memory cell arrays formed therein are arranged in a row direction and a column direction. The peripheral circuit region 38 with a peripheral circuit constituted from an IO buffer and the like formed therein is disposed on the periphery of each memory cell region 37.

Referring to FIGS. 9A and 9B, CMOS transistors that are the same as those in the second exemplary embodiment (refer to FIGS. 4A and 4B) are formed in the peripheral circuit region 38. However, in the gate electrode 32 of a P-type, between a P-type second silicon film 18a and a protective film 19, a P-type third silicon film 43a and a conductive film 44 are interposed in this stated order from a lower side. Similarly, in the gate electrode 33 of an N type as well, between an N-type second silicon film 18b and the protective film 19, an N-type third silicon film 43b and the conductive film 44 are interposed in this stated order from the lower side. On parts of an interlayer insulating film 27 including a contact plug 28 and a contact plug 29 (which may include the protective film 19), an interconnect 46a electrically connected to an N+ type source/drain region 26 of an N-channel transistor 31 via the contact plug 28 and an interconnect 46b electrically connected to a P+ type source/drain region 24 of a P-channel transistor 30 via the contact plug 29 are formed. An etching stopper film 47 is formed on an entire surface of a substrate including the interconnects 46a and 46b. An interlayer insulating film 48 is formed on the etching stopper film 47.

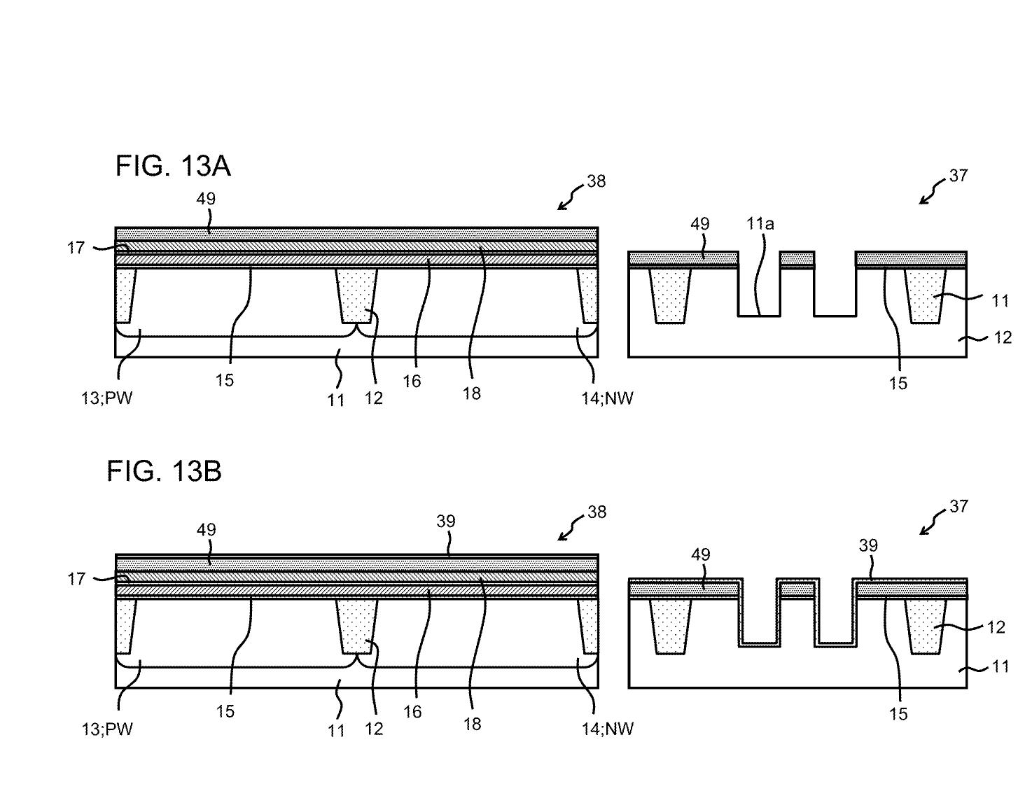

Referring to FIGS. 10A and 10B, 6F2 (cell area based on a design rule)/bWL (buried Word Line; buried word line) type memory cells are formed in the memory cell region 37. STIs (Shallow Trench Isolations; made of a silicon oxide film, for example) 12 for electrically isolating elements (transistors) are formed in a semiconductor substrate 11 (such a silicon substrate). Two trenches (indicated by reference numeral 11a in FIG. 13A) are formed in a region surrounded by the STIs 12 in the semiconductor substrate 11. A gate insulating film 39 (made of a silicon oxide film, for example) is formed on the surface (bottom surface and sidewall surfaces) of each of the trenches. Buried word lines 40 (made of a metal film, for example) are buried into the trenches through the gate insulating film 39 with the buried word lines 40 not fully filled in the trenches. The buried word lines 40 form gate electrodes. A gate insulating film 15, which is the same layer as the gate insulating film (indicated by reference numeral 15 in FIGS. 9A and 9B) used for the P-channel transistor (indicated by reference numeral 30 in FIGS. 9A and 9B) and the N-channel transistor (indicated by reference numeral 31 in FIGS. 9A and 9B) in the peripheral circuit region (indicated by reference numeral 38 in FIGS. 9A and 9B) is formed on regions of the semiconductor substrate 11 between the buried word line 40 and the STI 12 and the STI 12. The gate insulating film 15 and the gate insulating film 39 are not formed on a region of the semiconductor substrate 11 between the buried word lines 40. A bit contact interlayer insulating film 42 (formed of a silicon oxide film, for example) is formed on the gate insulating films 15 and 39 and the buried word line 40. The bit contact interlayer insulating film 42 is not formed on a region between the buried word lines 40. An N-type third silicon film 43c (BL; bit line) connected to the semiconductor substrate 11 (of a portion which will become a source region) is formed in a part of the bit contact interlayer insulating film 42 in a region between the buried word lines 40 including the semiconductor substrate 11. The protective film 19 (made of a silicon nitride film, for example) is formed over the N-type third silicon film 43c through the conductive film 44 (made of a metal film, a silicide film, or the like). A liner film 22 (made of a silicon nitride film or the like) is formed on sidewall surfaces of the protective film 19, the conductive film 44, and the buried word lines 40 and surfaces of the bit contact interlayer insulating film 42. An interlayer insulating film 27 (made of a silicon oxide film, for example) is formed on the liner film 22. The interlayer insulating film 27 does not cover the protective film 19 (may cover the protective film 19). A hole leading to a region of the semiconductor substrate 11 (which will become a drain region) between the buried word line 40 and the STI 12 is formed in the interlayer insulating film 27, the liner film 22, the bit contact interlayer insulating film 42, and the gate insulating film 15. A capacitance contact plug 45 (made of tungsten, for example) is buried in the hole.

A capacitance contact pad 46c (made of a metal film, for example) connected to the capacitance contact plug 45 is formed on a part of the interlayer insulating film 27 including the capacitance contact plug 45 (which may include the protective film 19) in the memory cell region 37. An etching stopper film 47 (made of a silicon nitride film, for example) is formed over the interlayer insulating film 27 including capacitance contact pad 46c and the protective film 19. An opening portion leading to the capacitance contact pad 46c is formed in the etching stopper film 47. A crown-like capacitor 50 is formed on the capacitance contact pad 46c. The capacitor 50 is made of a conductive film (lower electrode) 51, a dielectric film (capacitance film) 52, and a conductive film (upper electrode) 53 formed in this stated order from a lower side on the page of FIG. 10B. The conductive film 51 is connected to the capacitance contact pad 46c. The dielectric film 52 and the conductive film 53 are formed in the etching stopper film 47 as well. A plate electrode 54 (made of a metal film, for example) is formed on the conductive film 53.

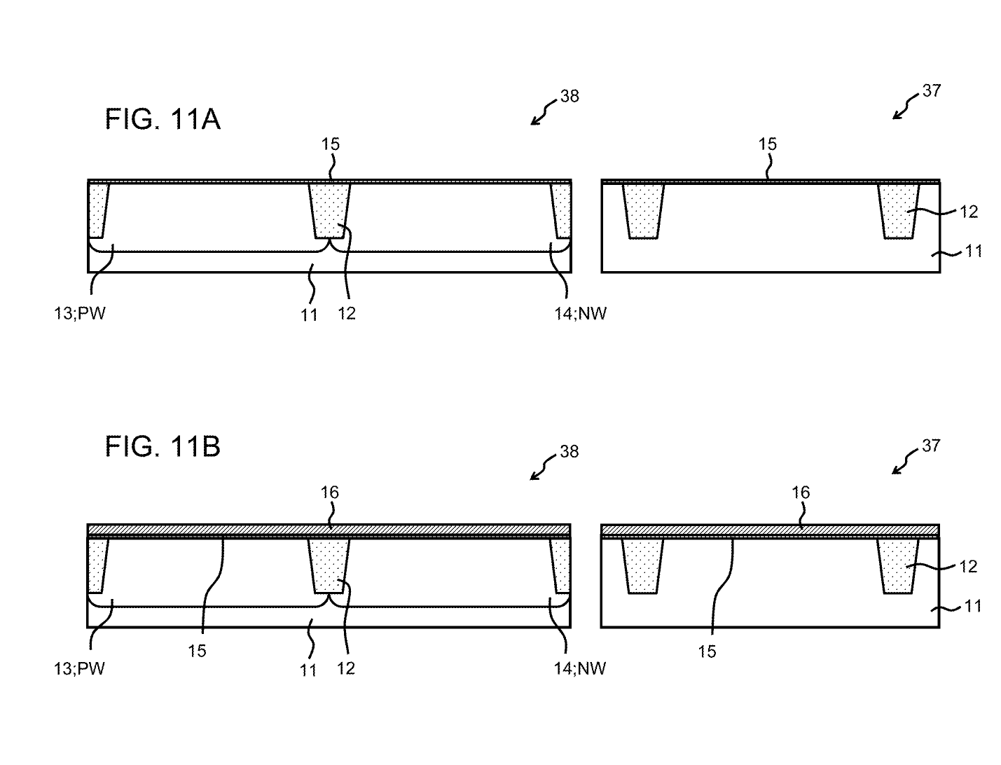

Next, a method of manufacturing the semiconductor device in the third exemplary embodiment will be described, using drawings. FIGS. 11A to 15B are sectional views schematically showing steps of the manufacturing method of the semiconductor device in the third exemplary embodiment.

First, the STIs 12 are formed in an element separation region of the semiconductor substrate 11. Then, a deep N-well (not shown) is formed in the semiconductor substrate 11 in the memory cell region 37. A P-well 13 and an N-well 14 are then formed in the semiconductor substrate 11 in the peripheral circuit region 38. A channel (not shown) is then formed. The gate insulating film 15 is formed on a main surface of the substrate including the STIs 12, the P well 13, and the N well 14 (in step C1; refer to FIG. 11A).

The STIs 12, the deep N-well (not shown; formed by ion implantation or the like), the P-well 13 (formed by ion implantation or the like), the N-well 14 (formed by ion implantation or the like), the channel (not shown; formed by ion implantation or the like), and the gate insulating film 15 (formed by thermal oxidation, or plasma oxynitriding) can be formed by a known method.

Next, a first silicon film 16 mainly made of silicon is formed on the gate insulating film 15 (in step C2; refer to FIG. 11B).

Though the first silicon film 16 will herein form gate electrodes (such as the gate electrodes 32 and 33 in FIGS. 9A and 9B) in the peripheral circuit region 38, the first silicon film 16 is also formed in the memory cell region 37 in this stage. The first silicon film 16 can be formed by a CVD method, for example. Though the first silicon film 16 is polycrystallized in a later heat treatment or the like, the first silicon film 16 formed in this step may be polycrystalline or amorphous. However, in order to reduce an increase in surface roughness of the first silicon film 16 resulting from enlargement of the grain size when the polycrystallization is performed by heating, it is preferable that the first silicon film 16 be formed in an amorphous state, in step C2. Preferably, the first silicon film 16 has a thickness of 30 nm or less.

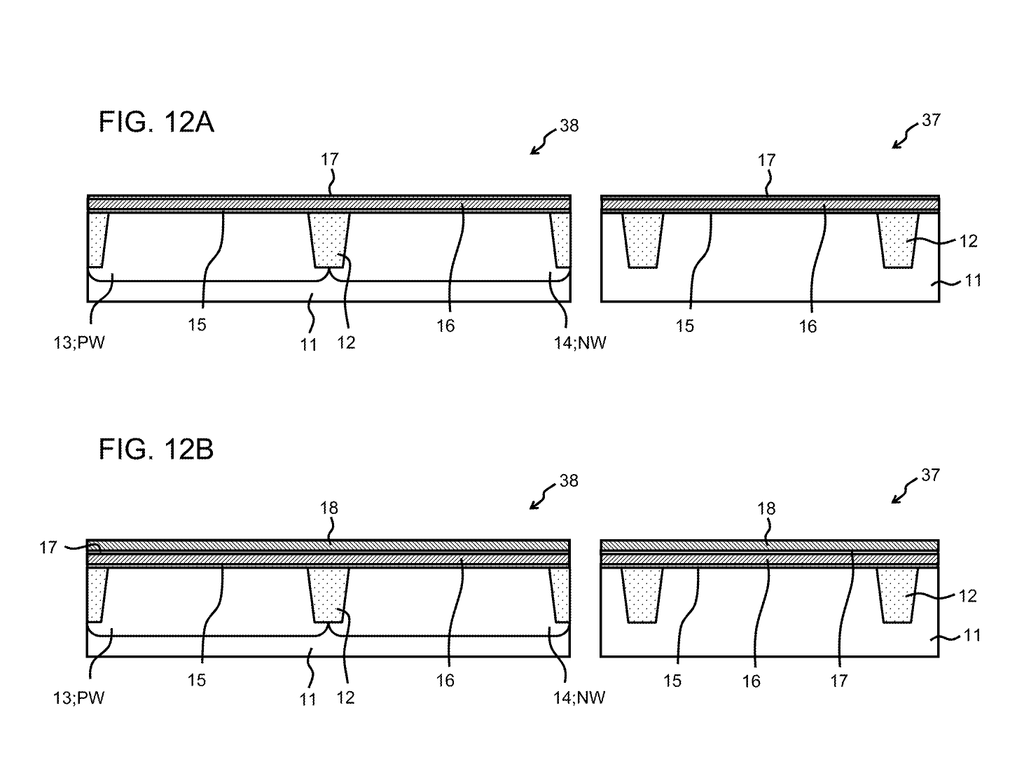

Next, at least one of oxygen and nitrogen is supplied to the surface of the first silicon film 16, thereby forming an intervening layer 17 mainly made of silicon including the at least one of oxygen and nitrogen (in step C3; refer to FIG. 12A).

The intervening layer 17 herein has a thickness of not less than one molecule layer and not more than 3.0 nm. More preferably, the intervening layer 17 has a thickness of not more than 2.0 nm. Preferably, the intervening layer 17 is formed at a position lower than a half of the entire film thickness of each gate electrode (film thickness from the lower surface of the first silicon film 16 to the upper surface of a second silicon film 18 on the page of FIG. 1). More specifically, it is more preferable that the intervening layer 17 be formed at a position of 30 nm or less from the interface between the gate insulating film 15 and the first silicon film 16 (in other words, the thickness of the first silicon film 16 to be formed in step C2 is set to 30 nm or less).

As a method of forming the intervening layer 17, the following two methods can be pointed out. In a first method of forming the intervening layer 17, at least one of an oxygen gas and a nitrogen gas is supplied to a same chamber after the first silicon film 16 has been formed. With this arrangement, a thin silicon oxide film, a thin silicon nitride film, or a thin silicon oxynitride film that will become the intervening layer 17 is formed on the surface of the first silicon film 16. Then, the second silicon film (indicated by reference numeral 18 in FIG. 12B) is formed in the same chamber. In a second method of forming the intervening layer 17, after the first silicon film 16 has been formed in a chamber, the first silicon film 16 is transferred to a different chamber to be subject to an oxidation process, a nitriding process, or an oxynitriding process. Alternatively, after the first silicon film 16 has been formed in the chamber, the first silicon film 16 is transferred to the different chamber. Then, the silicon oxide film, the silicon nitride film, or the silicon oxynitride film, which will become the intervening layer 17, is formed on the first silicon film 16. Then, the second silicon film (indicated by reference numeral 18 in FIG. 12B) is formed in the chamber where the first silicon film 16 has been formed.

Next, the second silicon film 18 mainly made of silicon is formed on the intervening layer 17 (in step C4; refer to FIG. 12B).

The second silicon film 18 can herein be formed by the CVD method, for example. Though the second silicon film 18 is polycrystallized by a later heat treatment or the like, the second silicon film 18 formed in step C4 may be polycrystalline or amorphous. However, in order to reduce an increase in surface roughness of the second silicon film 18 resulting from enlargement of the grain size when the polycrystallization is performed by heating, it is preferable that the second silicon film 18 be formed in an amorphous state, in step C4.

Next, the second silicon film 18, the intervening layer 17, and the first silicon film 16 in the memory cell region 37 are removed. Then, a hard mask 49 for forming the buried word lines (indicated by reference numeral 40 in FIGS. 10A and 10B) is formed on the substrate. Then, the trenches 11a are formed by etching the gate insulating film 15 and the semiconductor substrate 11 using the hard mask 49 as a mask (in step C5; refer to FIG. 13A).

Herein, when the second silicon film 18, the intervening layer 17, and the first silicon film 16 in the memory cell region 37 are removed, a photoresist is formed on the second silicon film 18 in the peripheral circuit region 38, for example. Then, the trenches 11a are formed by etching the second silicon film 18, the intervening layer 17, and the first silicon film 16 in the memory cell region 37 using the photoresist as a mask. The photoresist is then removed.

A silicon oxide film, a silicon nitride film, or one of other films that are highly selective with respect to dry etching of the semiconductor substrate 11, for example, can be used for the hard mask 49. Alternatively, the hard mask 49 can be formed by forming the hard mask 49 on the entire surface of the substrate (using the CVD method, for example), forming a photoresist including opening portions for the buried word lines (indicated by reference numeral 40 in FIGS. 10A and 10B) on the hard mask 49, etching the hard mask 49 using the photoresist as a mask, and then removing the photomask, for example.

Further, the trenches 11a are formed by dry etching the semiconductor substrate 11 including the gate insulating film 15 to a depth shallower than the depth of the bottom surface of each STI 12, for example.

Next, the gate insulating film (made of a silicon oxide film, for example) 39 for the transistors in the memory cell region 37 is formed over an entire surface of the substrate (in step C6; refer to FIG. 13B).

The gate insulating film 39 can herein be formed by thermal oxidation or plasma oxynitriding, for example. The silicon films 16 and 18 in the peripheral circuit region 38 that have been formed earlier are polycrystallized by this heat treatment. In the present disclosure, the intervening layer 17 is interposed between the silicon films 16 and 18. Thus, when each of the silicon films 16 and 18 is polycrystallized, enlargement of grains is reduced. Accordingly, it becomes less likely that the thickness of each of the silicon films 16 and 18 is locally reduced. When impurity ions are implanted into silicon films 16a, 16b, 18a, and 18b in later steps C8 and C9, this reduces penetration of the implanted impurity ions into a channel region through a location where the thickness of each of the silicon films 16a, 16b, 18a, and 18b is locally reduced. This can reduce a variation in the threshold of each transistor.

The heat treatment that may cause grain enlargement due to polycrystallization of the silicon films 16 and 18 is not limited to that for formation of the gate insulating film 39 for the transistors in the memory cell region 37 in step C6. That is, when the semiconductor device manufacturing method includes steps of applying heat treatment and applying ion implantation after formation of the silicon films 16 and 18 which will form the gate electrodes in the peripheral circuit region 38, the present disclosure is likewise effective by applying the intervening layer 17 of the present disclosure to that manufacturing method. The gate insulating film 39 in the memory cell region 37, however, needs heat treatment at a higher temperature. Accordingly, grain sizes of each of the silicon films 16 and 18 in the peripheral circuit region 38 that have been formed earlier may be more increased. Accordingly, the present disclosure is more effective when the intervening layer 17 of the present disclosure is applied to the semiconductor device manufacturing method including the step such as step C6 of applying heat treatment for forming the gate insulating film 39 for the transistors in the memory cell region 37 after formation of the silicon films 16 and 18 in the peripheral circuit region 38.

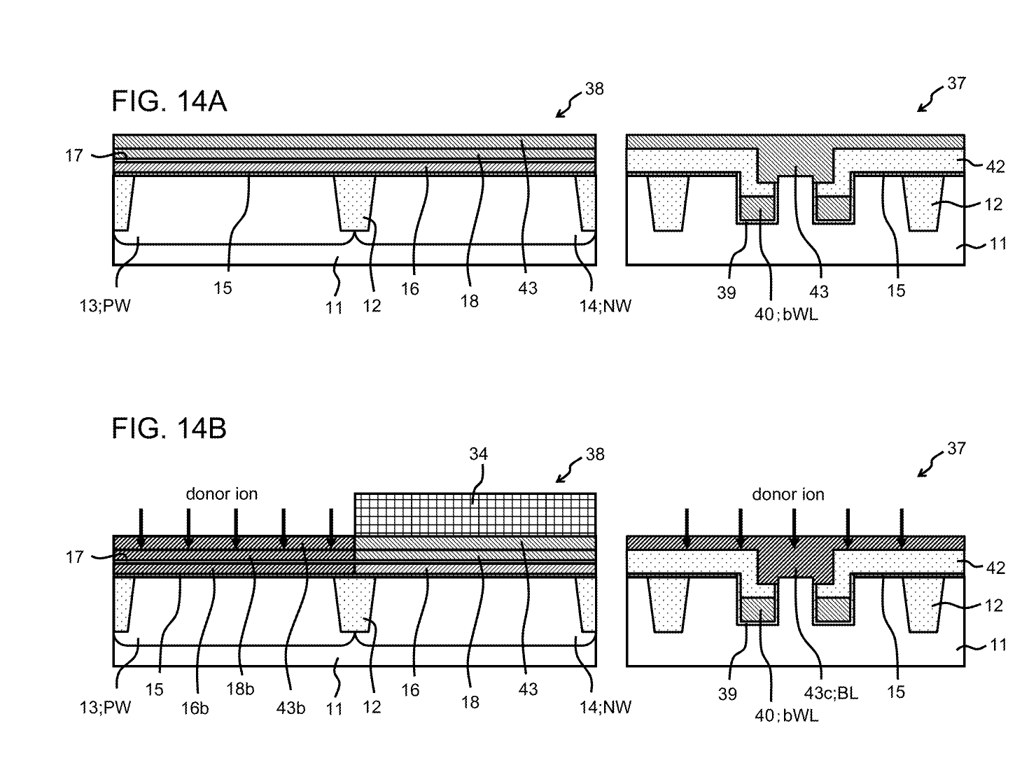

Next, the buried word lines 40 (made of a conductive film, for example) are formed on the gate insulating film 39 within the trenches (indicated by reference numeral 11a in FIG. 13A). Then, the gate insulating film 39 (portions of the gate insulating film 39 on the hard mask 49) and the hard mask 49 are removed. The bit contact interlayer insulating film 42 (made of the silicon oxide film, for example) is formed on the entire surface of the substrate. An opening portion leading to the semiconductor substrate 11 (which will become a source region) is then formed in a region of the bit contact interlayer insulating film 42 between the buried word lines 40. Then, a third silicon film 43 is formed on an entire surface of the substrate (in step C7; refer to FIG. 14A).

The buried word lines 40 can herein be formed on the gate insulating film 30 within the trenches (indicated by reference numeral 11a in FIG. 13A) by depositing the conductive film on the entire surface of the substrate and then removing unnecessary portions of the conductive film by etchback, for example.

The opening portion in the bit contact interlayer insulating film 42 can be formed by forming a photoresist for formation of the opening portion on the bit contact interlayer insulating film 42, and then etching the bit contact interlayer insulating film 42 using the photoresist as a mask, for example.

The third silicon film 43 can be formed by the CVD method, for example. The third silicon film 43 becomes a portion of each of the gate electrodes (such as those indicated by reference numerals 32 and 33 in FIGS. 9A and 9B) in the peripheral circuit region 38, and becomes a portion of each bit line in the memory cell region 37.

Next, a photoresist 34 is formed on the third silicon film 43 in a region of the peripheral circuit region 38 where the N-well 14 is formed. Then, using the photoresist 34 as a mask, donor ions (of As, P, or the like) are implanted into a region of the peripheral circuit region 38 where the P-well 13 is formed, and the silicon films 18b, 16b, 43b, and 43c of the memory cell region 37 (step C8; refer to FIG. 14B). Then, the photoresist 34 is removed.

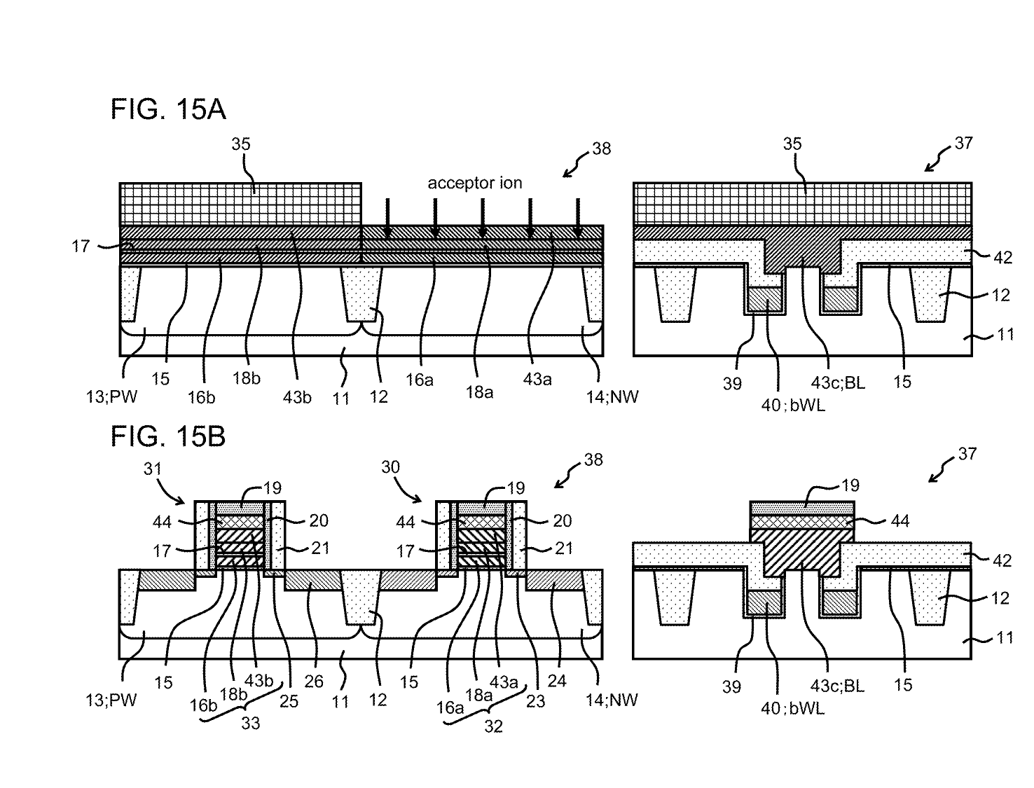

Next, a photoresist 35 is formed on a region of the peripheral circuit region 38 where the P-well 13 is formed and the N-type third silicon films 43b and 43c of the memory cell region 37. Then, accepter ions (of B or the like) are implanted into the silicon films 43a, 18a, and 16a in the region of the peripheral circuit region 38 where the N-well 14 is formed (in step C9, refer to FIG. 15A). The photoresist 35 is then removed.

The step C8 may be interchanged with step C9 with respect to the order of application. When the step C8 and the step C9 are executed, the intervening layer 17 functions as a stopper to prevent the implanted ions from reaching the channel region. This can reduce a variation in the threshold voltage of each transistor.

In the third exemplary embodiment, the intervening layer 17 is interposed between the silicon films 16a and 18a and between the silicon films 16b and 18b. An increase in roughness due to grain enlargement of the silicon films 16a, 16b, 18a, 18b, 43a, and 43b is reduced in the heat treatment (for formation of the gate insulating film 39) in step C6 and the like. Accordingly, it becomes less likely that the thickness of each of the silicon films 16a, 16b, 18a, and 18b is locally reduced. Accordingly, when the impurity ions are implanted into the silicon films 16a, 16b, 18a, and 18b in steps C8 and C9, the implanted impurity ions may be prevented from being implanted into the channel region through a location where the thickness of each of the silicon films 16a, 16b, 18a, 18b, 43a and 43b is locally reduced. As a result, this can reduce a variation in the threshold of each transistor.

Further, by introducing the intervening layer 17 between the silicon films 16a and 18a and between the silicon films 16b and 18b, an amount of the implanted ions that will reach the channel region can be reduced. Further, even when annealing for diffusion and activation of the implanted impurity ions is performed, the ions that will reach the channel region can be reduced. Consequently, a variation in the threshold voltage of each transistor can be further reduced. This operation and effect is more effective for the P-type gate electrode (indicated by reference numeral 32 in FIGS. 9A and 9B) of the P-channel transistor for which implantation of boron (B) is performed.

Next, the entire substrate is heated (for activation annealing). Then, the conductive film 44 (made of the metal film or the silicide film, for example) is formed on the entire surface of the substrate. The protective film 19 (made of the silicon nitride film, for example) is formed on regions of the conductive film 44 that will be left as the gate electrodes 32 and 33 and the bit line (made of the N-type third silicon film 43c). Then, using the protective film 19 as a mask, the conductive film 44, the third silicon films 43a, 43b, and 43c, the second silicon films 18a and 18b, the intervening layer 17, the first silicon films 16a and 16b, and the gate insulating film 15 are etched until the P-well 13 and the N-well 14 are exposed. Then, in the peripheral circuit region 38 alone, sidewall-like offset spacers 20 (made of a silicon nitride film, for example) are formed on sidewalls of the protective film 19, the P-type second silicon film 18a, the intervening layer 17, the P-type first silicon film 16a, and the gate insulating film 15 in the region where the N-well 14 is formed and on sidewalls of the protective layer 19, the N-type second silicon film 18b, the intervening layer 17, the N-type first silicon film 16b, and the gate insulating film 15 in the region where the P-well 13 is formed. Then, LDD regions (which are an N-type LDD region 25 in the P-well 13 and a P-type LDD region 23 in the N-well 14) are formed. Then, in the peripheral circuit region 38 alone, sidewalls 21 (made of a silicon oxide film, for example) are formed on sidewalls of the offset spacers 20. Then, source/drain regions (which are the N+ type source/drain region 26 formed in the P-well 13 and the P+ type source/drain region 24 formed in the N-well 14) are formed (in step C10; refer to FIG. 15B). With this arrangement, the bit line in the memory cell region 37 and the transistors in the peripheral circuit region 38 are completed.

The conductive film 44 forms portions of the gate electrodes 32 and 33 in the peripheral circuit region 38 and a portion of the bit line (BL) in the memory cell region 37. Heat treatment, formation of the protective film 19, formation of the offset spacers 20, formation of the LDD regions 23 and 25, formation of the sidewalls 21, and formation of the source/drain regions 24 and 26 are performed in the same manner as in steps B7 and B8 in the second exemplary embodiment.

Finally, the liner film 22 (made of the silicon nitride film, for example) is formed over the entire surface of the substrate including the P-channel transistor 30 and the N-channel transistor 31. Then, the interlayer insulating film 27 is formed over the liner film 22. The resulting surface of the substrate is then planarized (by CMP, for example). Then, hole(s) leading to the source/drain regions 24 and 26 are formed in the interlayer insulating film 27 and the liner film 22 in the peripheral circuit region 38. A hole leading to the semiconductor substrate 11 (portion which will become a drain region) is formed in a region between the buried word line 40 and the STI 12 in the memory cell region 37. Then, the contact plugs 28 and 29 and the capacitance contact plug 45 (made of tungsten, for example) are formed in the hole(s). Then, an interconnect 46a connected to the contact plug 28, an interconnect 46b connected to the contact plug 29, and a capacitance contact pad 46c (made of a conductive film, for example) connected to the capacitance contact plug 45 are formed on portions of the interlayer insulating film 27 including the contact plugs 28 and 29 and the capacitance contact plug 45. The etching stopper film 47 (made of the silicon nitride film, for example) is formed on the interlayer insulating film 27 including the interconnects 46a and 46b and the capacitance contact pad 46c. Then, the crown capacitor 50 is formed (in step C11; refer to FIGS. 9A to 10B). After step C11, known steps of forming interconnects, an interlayer insulating film, via plugs, and upper layer interconnects follow.

The interconnects 46a and 46b and the capacitance contact pad 46c can herein be formed by forming a conductive film on the entire surface of the substrate by the CVD method, forming a photoresist on the conductive film that will be left as the interconnects 46a and 46b and the capacitance contact pad 46c, and then etching the conductive film until the interlayer insulating film 27 is exposed, using the photoresist as a mask, for example.

The crown capacitor 50 can be formed by forming the interlayer insulating film 48 (made of a silicon oxide film, for example) on the etching stopper film 47, forming a hole leading to the capacitance contact pad 46c in the interlayer insulating film 48 and the etching stopper 47 in the memory cell region 37, forming the conductive film 51 (lower electrode) on the surface (bottom surface and sidewall surfaces) of the hole, etching and removing the interlayer insulating film 48 in the memory cell region 37, forming the dielectric film (capacitance film) 52 on the entire surface of the memory cell region 37, forming the conductive film (upper electrode) 53 on the dielectric film 52, and then forming a plate electrode 54 on the conductive film 53 in the memory cell region 37, for example.

Formation of the liner film 22, formation of the interlayer insulating film 27, formation of the hole(s), and formation of the contact plugs 28 and 29 and the capacitance contact plug 45 are performed in the same manner as in step B9 in the second exemplary embodiment.

According to the third exemplary embodiment, the silicon films 16 and 18 in the peripheral circuit region 38 that have been formed earlier are polycrystallized due to heat treatment when the gate insulating film 39 for the transistors in the memory cell region 37 is formed. In the present disclosure, the intervening layer 17 is interposed between the silicon films 16 and 18. Thus, when the silicon films 16 and 18 are polycrystallized, the grain enlargement is reduced. Accordingly, it becomes less likely that the thickness of each of the silicon films 16 and 18 is locally reduced. When the impurity ions are implanted into the silicon films 16a, 16b, 18a, 18b, 43a, and 43b in later steps C8 and C9, this arrangement reduces penetration of the implanted impurity ions into the channel region through a location where the thickness of each of the silicon films 16a, 16b, 18a, 18b, 43a, and 43b is locally reduced. This can reduce a variation in the threshold of each transistor.

Further, according to the third exemplary embodiment, the intervening layer 17 is introduced between the silicon films 16 and 18. Thus, an amount of the implanted ions that will reach the channel region can be reduced. Then, even in annealing for diffusing and activating the implanted impurity ions, the ions that will reach the channel region can be reduced. As a result, a variation in the threshold voltage of each transistor can be further reduced. This effect is more effective for the P-channel transistor 30 for which implantation of boron (B) is performed.

### Fourth Exemplary Embodiment

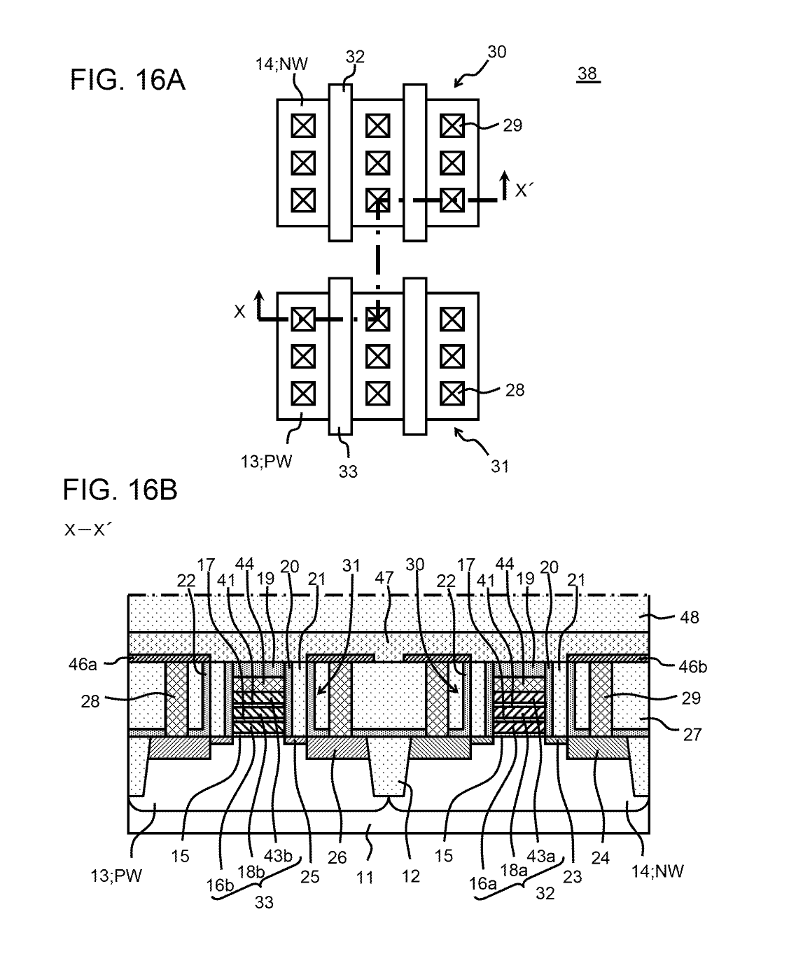

A semiconductor device in a fourth exemplary embodiment of the present disclosure will be described using drawings. FIGS. 16A and 16B are respectively a plan view and a sectional view taken along a line X-X′ of FIG. 16A, each schematically showing a configuration of a peripheral circuit region of the semiconductor device according to the fourth exemplary embodiment.

The fourth exemplary embodiment is a variation example of the third exemplary embodiment. Two intervening layers, which are an intervening layer 17 and an intervening layer 41 are provided for each of gate electrodes 32 and 33 in a peripheral circuit region 38. As in the second exemplary embodiment, the intervening layer 17 is a layer interposed between silicon films 16a and 18a, and between silicon films 16b and 18b. The intervening layer 17 is mainly made of silicon and includes at least one of oxygen and nitrogen. The intervening layer 41 is a layer interposed between the silicon film 18a and a silicon film 43a, and between the silicon film 18b and a silicon film 43b. The intervening layer 41 is mainly made of silicon and includes at least one of oxygen and nitrogen. Other configurations in the peripheral circuit region 38 and a configuration of a memory cell region (not shown) are the same as those in the third exemplary embodiment.

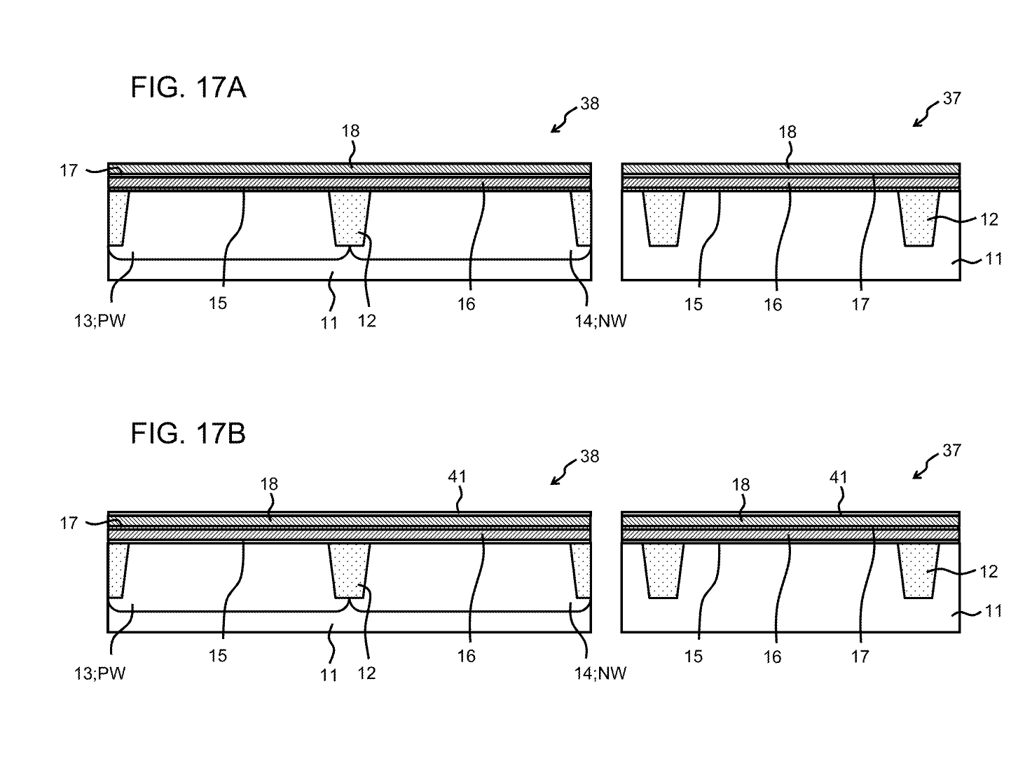

Next, a manufacturing method of the semiconductor device according to the fourth exemplary embodiment of the present disclosure will be described using drawings. FIGS. 17A and 17B are sectional views schematically showing steps of the manufacturing method of the semiconductor device according to the fourth exemplary embodiment of the present disclosure.

First, STIs 12, a P-well 13, and an N-well 14, a gate insulating film 15 are formed in a semiconductor substrate 11, and a first silicon film 16, the intervening layer 17, and a second silicon film 18 are formed on the semiconductor substrate 11, as in steps C1 to C4 in the third exemplary embodiment (in step D1; refer to FIG. 17A).

Next, the intervening layer 41 is formed on the second silicon film 18 (in step D2; refer to FIG. 17B). The intervening layer 41 can be formed in the same manner as the intervening layer 17.

Then, same steps as steps C5 to C11 in the third exemplary embodiment are carried out (in step D3).

The fourth exemplary embodiment has a similar effect to the second and third exemplary embodiments. Further, by providing two intervening layers 17 and 41, the fourth exemplary embodiment can accommodate a case where a required film thickness of each silicon layer and a required position of the silicon layer are different with respect to achievement of the barrier effect for ion implantation (as in the second exemplary embodiment) and achievement of the effect of reducing grain enlargement (as in the third exemplary embodiment), for example.

Reference symbols in the drawings of the present application are used solely for facilitating understanding, and are not intended for limiting the disclosure to an illustrated mode.

Modifications and adjustments of the exemplary embodiments and an example are possible within the scope of the overall disclosure (including claims and the drawings) of the present disclosure, and based on the basic technical concept of the invention. Various combinations and selections of various disclosed elements are possible within the scope of the claims of the present disclosure. That is, the present disclosure of course includes various variations and modifications that could be made by those skilled in the art according to the overall disclosure including the claims and the drawings and the technical concept.

In the present disclosure there are possible modes, by way of examples, as follows.

### Mode 1.

A semiconductor device, comprising a field effect transistor, the field effect transistor including: a first gate electrode film formed over a main surface of a semiconductor substrate intervened with a gate insulating film, the first gate electrode film being mainly made of silicon and including an impurity that is to be of a first conductivity type; an intervening layer formed on the first gate electrode film, the intervening layer being mainly made of silicon including at least one of oxygen and nitrogen; and a second gate electrode film formed on the intervening layer, the second gate electrode film being mainly made of silicon and including the impurity that is to be of the first conductivity type.

### Mode 2.

In the semiconductor device, the intervening layer may have a thickness of not less than one molecule layer and not more than 3 nm.

### Mode 3.

In the semiconductor device, the intervening layer may have a thickness of not more than 2 nm.

### Mode 4.

In the semiconductor device, the intervening layer may be formed at a position lower than a half of a film thickness of an entire gate electrode including the first gate electrode film, the intervening layer, and the second gate electrode film.

### Mode 5.

In the semiconductor device, the first gate electrode film may have a thickness of not more than 30 nm.

### Mode 6.

In the semiconductor device, the impurity that is to be of the first conductivity type may be boron.

### Mode 7.

The semiconductor device may comprise: another field effect transistor in a region other than a region where the field effect transistor is formed, wherein the another field effect transistor may include: another first gate electrode film formed over the main surface of the semiconductor substrate intervened with another gate insulating film, the another first gate electrode film being formed on a same layer as the first gate electrode film, being mainly made of silicon, and including an impurity that is to be of a second conductivity type opposite to the first conductivity type; another intervening layer formed on the another first gate electrode film, the another intervening layer being formed on a the layer as the intervening layer, being mainly made of silicon, and including at least one of oxygen and nitrogen; and another second gate electrode film formed over the another first gate electrode film intervened with the another intervening layer, the another second gate electrode film being formed on a same layer as the second gate electrode film, being mainly made of silicon, and including the impurity that is to be of the second conductivity type.

### Mode 8.

In the semiconductor device, the field effect transistor may include a third gate electrode film formed on the second gate electrode film, the third gate electrode film being mainly made of silicon and including an impurity that is to be of the first conductivity type.

### Mode 9.

The semiconductor device, the field effect transistor may include: a second intervening layer formed on the second gate electrode film, the second intervening layer being mainly made of silicon and including at least one of oxygen and nitrogen; and a third gate electrode film formed over the first gate electrode film intervened with the second intervening layer, the third gate electrode film being mainly made of silicon and including an impurity that is to be of the first conductivity type.

### Mode 10.

The semiconductor device, wherein the semiconductor device may comprise a memory cell region having memory cells formed therein and a peripheral circuit region on a periphery of the memory cell region, the peripheral circuit region having circuit(s) formed therein; the field effect transistor may be formed in the peripheral circuit region; and the memory cell region may include buried word line type memory cells, each of the memory cells including a trench formed in the semiconductor substrate and a buried word line formed in the trench intervened with a second gate insulating film different from the gate insulating film.

### Mode 11.

A method of manufacturing a semiconductor device, comprising: forming a first silicon film over a main surface of a semiconductor substrate intervened with an insulating film, the first silicon film being mainly made of silicon; forming on the first silicon film an intervening layer mainly made of silicon and including at least one of oxygen and nitrogen; forming over the first silicon film a second gate electrode film mainly made of silicon, intervened with the intervening layer; and implanting, from the second silicon film side, impurity ions into the first silicon film and the second silicon film.

### Mode 12.

In the method of manufacturing a semiconductor device, when forming the intervening layer, the intervening layer may be formed by supplying the at least one of oxygen and nitrogen to a surface of the first silicon film in a chamber being identical with a chamber used when forming the first silicon film.

### Mode 13.

In the method of manufacturing a semiconductor device, when forming the intervening layer, the intervening layer may be formed by supplying the at least one of oxygen and nitrogen to a surface of the first silicon film in a chamber different from a chamber used when forming the first silicon film.

### Mode 14.

In the method of manufacturing a semiconductor device, when forming the intervening layer, the intervening layer may be formed by forming a silicon oxide film, a silicon nitride film, or a silicon oxynitride film, in a chamber different from a chamber used when forming the first silicon film.

### Mode 15.

In the method of manufacturing a semiconductor device, when forming the first silicon film, the first silicon film may be formed in an amorphous state.

### Mode 16.

In the method of manufacturing a semiconductor device, when forming the second silicon film, the second silicon film may be formed in an amorphous state.

### Mode 17.

In the method of manufacturing a semiconductor device, when implanting the impurity ions, acceptor ions may be implanted.

### Mode 18.

In the method of manufacturing a semiconductor device, when implanting the impurity ions, boron ions may be implanted.

### Mode 19.

In the method of manufacturing a semiconductor device, when implanting the impurity ions, acceptor ions may be implanted into a region of the semiconductor device where a P-channel transistor may be formed, and donor ions may be implanted into a region of the semiconductor device where an N-channel transistor is formed.

### Mode 20.

The method of manufacturing a semiconductor device may further comprise: forming on the second silicon film a third silicon film mainly made of silicon after forming the second silicon film and before implanting the impurity ions.

### Mode 21.

The method of manufacturing a semiconductor device may comprise: after forming the second silicon film and before implanting the impurity ions, forming on the second silicon film a second intervening layer mainly made of silicon and including at least one of oxygen and nitrogen; and forming over the second silicon film a third silicon film mainly made of silicon, intervened with the second intervening layer.

### Mode 22.

The method of manufacturing a semiconductor device may comprise: after forming the second silicon film and before implanting the impurity ions, removing the second silicon film, the intervening layer, and the first silicon film formed in a memory cell region, the semiconductor device including the memory cell region having memory cells formed therein and a peripheral circuit region on a periphery of the memory cell region having circuits formed therein; forming trenches in the semiconductor substrate in the memory cell region; and applying heat treatment for forming a gate insulating film to surfaces of the trenches.

What is claimed is:

1. A semiconductor device having a first conductive type transistor and a second conductive type transistor formed on a substrate,
the first conductive type transistor comprising:
a first lower gate electrode portion formed on the substrate, the first lower gate electrode portion comprising silicon including first impurity ions;
a first intervening layer formed on the first lower gate electrode portion, the first intervening layer comprising silicon including at least one of oxygen and nitrogen; and
a first upper gate electrode portion formed on the first intervening layer, the first upper gate electrode portion comprising silicon including the first impurity ions, and
the second conductive type transistor comprising:
a second lower gate electrode portion formed on the substrate, the second lower gate electrode portion comprising silicon including second impurity ions;
a second intervening layer formed on the second lower gate electrode portion, the second intervening layer comprising silicon including at least one of oxygen and nitrogen; and
a second upper gate electrode portion formed on the second intervening layer, the second upper gate electrode portion comprising silicon including the second impurity ions.

2. The device as claimed in claim 1, wherein the first intervening layer is configured to allow through conductive carriers between the first lower and upper gate electrode portions.

3. The device as claimed in claim 1, wherein voltage of the first lower gate electrode portion is controlled by a drift of conductive carriers between the first lower and upper gate electrode portions through the first intervening layer.

4. The device as claimed in claim 1, wherein a thickness of the first intervening layer is not more than 3 nm.

5. The device as claimed in claim 4, wherein the thickness of the first intervening layer is not more than 2 nm.

6. The device as claimed in claim 1, wherein the first lower gate electrode portion is smaller in thickness than the first upper gate electrode portion.

7. The device as claimed in claim 6, wherein a thickness of the first lower gate electrode portion is not more than 30 nm.

8. The device as claimed in claim 1, wherein the first impurity ions comprise boron, and the first conductive type is p-type.

9. The device as claimed in claim 1, further comprises:
a memory cell array having a plurality of units comprising a capacitor and a select transistor; and
a peripheral circuit comprising the first conductive type transistor and the second conductive type transistor, the peripheral circuit being configured to control an operation of the memory cell array.

10. The device as claimed in claim 1, wherein the first conductive type transistor further comprises:
a first top gate electrode portion formed on the first upper gate electrode portion, the first top gate electrode portion comprising silicon including the first impurity ions.

11. The device as claimed in claim 1, wherein the first conductive type transistor further comprises:
a third intervening layer formed on the first upper gate electrode portion, the third intervening layer comprising silicon including at least one of oxygen and nitrogen; and
a first top gate electrode portion formed on the third intervening layer, the first top gate electrode portion comprising silicon including first impurity ions.

12. A method of manufacturing a semiconductor device comprising:
forming a first silicon film on a substrate;
forming an intervening layer on the first silicon film, the first intervening layer comprising silicon including at least one of oxygen and nitrogen;
forming a second silicon film on the intervening layer;
implanting, from the second silicon film side, first impurity ions into a first portion of the first and second silicon films;
implanting, from the second silicon film side, second impurity ions into a second portion of the first and second silicon films;
thermally annealing, after implanting the first and second impurity ions, the substrate to activate the first and second impurity ions such that the first portion of the first and second silicon films is converted in a first conductive type and the second portion of the first and second silicon films is converted in a second conductive type;
selectively removing the first portion of the first and second silicon films to form a first gate electrode having the first conductive type; and
selectively removing the second portion of the first and second silicon films to form a second gate electrode having the second conductive type.

13. The method as claimed in claim 12, further comprising:
thermally annealing the substrate after forming the intervening layer and before forming the second silicon film.

14. The method as claimed in claim 12, wherein the intervening layer is formed in thickness of not more than 3 nm.

15. The method as claimed in claim 14, wherein the intervening layer is formed in thickness of not more than 2 nm.

16. The method as claimed in claim 12, wherein the first silicon film is formed in smaller thickness than the second silicon film.

17. The method as claimed in claim 12, wherein the first silicon film is formed in thickness of not more than 30 nm.

18. The method as claimed in claim 12, wherein the intervening layer is formed by performing at least one of an oxidation process and a nitriding process of a surface of the first silicon film, the oxidation process and the nitriding process being performed in a chamber that is identical with a chamber used in forming the first silicon film.

19. The method as claimed in claim 12, further comprising:
forming a memory cell array having a plurality of units comprising a capacitor and a select transistor; and
electrically connecting the select transistor to at least one of the first and second gate electrodes by a wire formed on the substrate.

20. The method as claimed in claim 12, wherein boron ions are implanted as the first impurity ions into the first portion of the first and second silicon films such that the first conductive type of the first gate electrode is to be p-type.
